(19) United States
(12) Patent Application Publication
(10) Pub. No.: US 2025/0326887 A1
(43) Pub. Date: Oct. 23, 2025

(54) RESIN COMPOSITION FOR LENSES, PHOTOSENSITIVE RESIN COMPOSITION, METHOD FOR MANUFACTURING DISPLAY DEVICE INCLUDING LENS, DISPLAY DEVICE, AND ELECTRONIC DEVICE COMPRISING DISPLAY DEVICE

(71) Applicant: Samsung Display Co., LTD., Yongin-si (KR)

(72) Inventors: Ji Hye LIM, Yongin-si (KR); Woong Sik KIM, Yongin-si (KR); Hyun Sook KIM, Yongin-si (KR); Si Woo YANG, Yongin-si (KR); Chang Woo LEE, Yongin-si (KR); Jung Han SHIN, Yongin-si (KR)

(21) Appl. No.: 19/092,423

(22) Filed: Mar. 27, 2025

(30) Foreign Application Priority Data
Apr. 17, 2024 (KR) 10-2024-0051077

(51) Int. Cl. C08G 61/12; G02B 1/04; G03F 7/00; G03F 7/004; H10K 59/80

(52) U.S. Cl. CPC C08G 61/124; G02B 1/041; G03F 7/0007; G03F 7/0045; C08G 2261/135; C08G 2261/3241; C08G 2261/76; H10K 59/879

(57) ABSTRACT

Provided herein is a resin composition for lenses, a photosensitive resin composition, a method for manufacturing a display device including a lens, a display device including a lens, and an electronic device comprising the display device. The resin composition for lenses may include solid content, and an organic solvent. The solid content may include: a resin material including a carbazole-based material and an acrylate-based material; a multifunctional cross-linker; an initiator including a thermal initiator and a photoinitiator; and a sensitizer.

### CROSS-REFERENCE TO RELATED APPLICATION

The present application claims priority to and the benefit of Korean Patent Application No. 10-2024-0051077, filed on Apr. 17, 2024 in the Korean Intellectual Property Office, the entire disclosure of which is incorporated herein by reference.

### BACKGROUND

### 1. Field

One or more embodiments of the present disclosure relate to a resin composition for lenses, a photosensitive resin composition, a method for manufacturing a display device including a lens utilizing the resin composition, a display device including a lens utilizing the resin composition, and an electronic device comprising the display device.

### 2. Description of Related Art

Recently, as interest in information display devices increases, research and development on such display devices have been continuously conducted. A display device may include a plurality of layers. For example, the display device may include a lens structure configured to refract a path of light applied thereto. The lens structure may improve optical characteristics (e.g., light output efficiency) of the display device.

The lens structure may have various suitable physical properties. In order for the lens structure to be properly manufactured, it is beneficial to reduce the risks that may arise during the process of manufacturing the lens structure.

### SUMMARY

One or more embodiments of the present disclosure are directed towards a resin composition for lenses, a photosensitive resin composition, a method for manufacturing a display device including a lens, a display device including a lens, and an electronic device comprising the display device, in which a lens structure utilizing the resin composition may have excellent high refractive characteristics, so that light output efficiency of the display device having the lens structure may be enhanced.

One or more embodiments of the present disclosure are directed towards a resin composition for lenses, a photosensitive resin composition, a method for manufacturing a display device including a lens, a display device including a lens, and an electronic device comprising the display device, in which a lens having a suitable or desired thickness may be suitably or appropriately formed.

One or more embodiments of the present disclosure are directed towards a resin composition for lenses, a photosensitive resin composition, a method for manufacturing a display device including a lens, a display device including a lens, and an electronic device comprising the display device, in which process risk may be reduced during a process of manufacturing the lens, and process performance may be enhanced.

One or more embodiments of the present disclosure are directed towards a resin composition for lenses including solid content and an organic solvent. The solid content may include a resin material including a carbazole-based material and an acrylate-based material, a multifunctional cross-linker, an initiator including a thermal initiator and a photoinitiator, and a sensitizer.

In one or more embodiments, an amount of the carbazole-based material may be about 75 wt % to about 95 wt % relative to 100 wt % of a total weight of the solid content. The amount of acrylate-based material may be about 1 wt % to about 15 wt % relative to 100 wt % of the total weight of the solid content.

In one or more embodiments, the carbazole-based material may include poly(9-vinylcarbazole) represented by Chemical Formula 1-1. The acrylate-based material may include benzyl methacrylate represented by Chemical Formula 1-2.

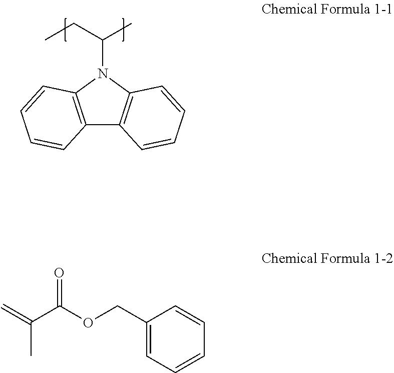

In one or more embodiments, the resin material may have a refractive index in a range from about 1.55 to about 1.75 with respect to light having a wavelength of 400 nm.

In one or more embodiments, an amount of the multifunctional cross-linker may be about 1 wt % to about 15 wt % relative to 100 wt % of a total weight of the solid content. The multifunctional cross-linker may include a material represented by Chemical Formula 2-1 and/or a material represented by Chemical Formula 2-2.

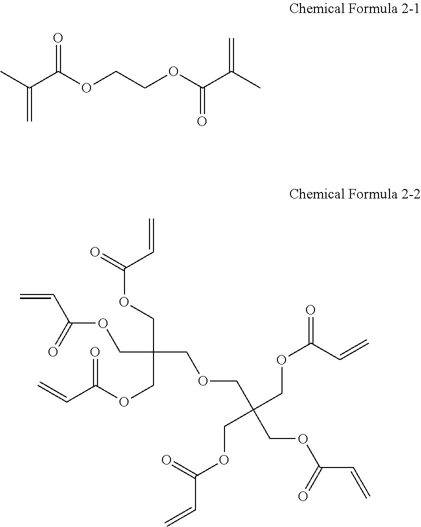

In one or more embodiments, an amount of the thermal initiator may be about 0.5 wt % to about 5 wt % relative to 100 wt % of the total weight of the solid content. An amount of photoinitiator may be about 0.1 wt % to about 10 wt % relative to 100 wt % of the total weight of the solid content. The thermal initiator may include a material represented by Chemical Formula 3-1. The photoinitiator may include at least one selected from among a material represented by Chemical Formula 3-2 and/or a material represented by Chemical Formula 3-3.

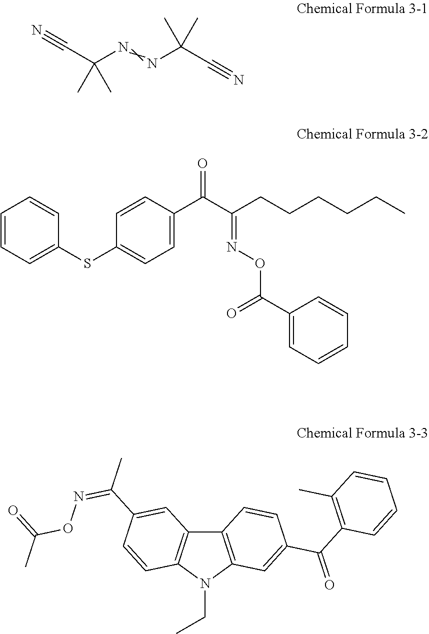 [SMILES: CC(C)(C#N)N=NC(C)(C)C#N ; CCCCCC/C(=N\OC(=O)c1ccccc1)C(=O)c1ccc(Sc2ccccc2)cc1 ; CCn1c2ccc(/C(C)=N\OC(C)=O)cc2c2ccc(C(=O)c3ccccc3C)cc21]

In one or more embodiments, the resin composition may further include an auxiliary initiator including a hydroxyl group. The auxiliary initiator may include one or more selected from among a material represented by Chemical Formula 4-1, a material represented by Chemical Formula 4-2, a material represented by Chemical Formula 4-3, a material represented by Chemical Formula 4-4, and a material represented by Chemical Formula 4-5.

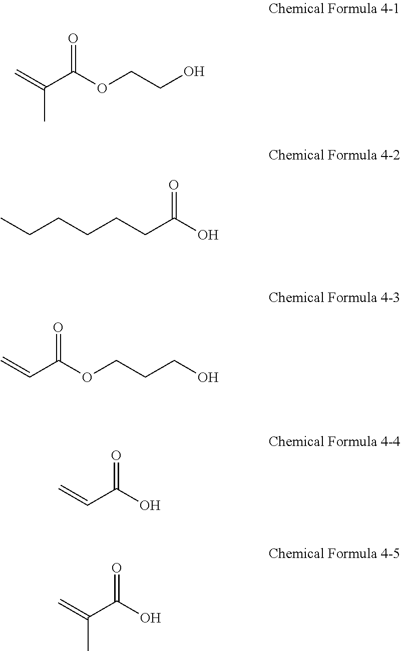

In one or more embodiments, the resin composition may further include a sensitizer represented by Chemical Formula 5-1 and/or Chemical Formula 5-2, and an amount of the sensitizer represented by Chemical Formula 5-1 and/or Chemical Formula 5-2 may be about 0.1 wt % to about 5 wt % relative to 100 wt % of the total weight of the solid content.

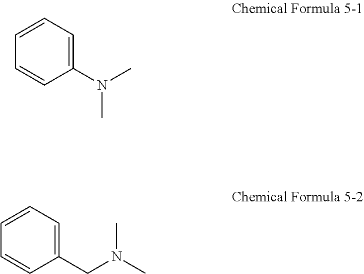

In one or more embodiments, an amount of the organic solvent may be about 60 wt % to about 90 wt % relative to 100 wt % of the total weight of the resin composition, and the resin composition may have a viscosity in a range from about 10 cP to about 30 cP.

In one or more embodiments, the organic solvent may include one or more selected from among propylene glycol monomethyl ether (PGME) and/or propylene glycol methyl ether acetate (PGMEA).

One or more embodiments of the present disclosure are directed towards a photosensitive resin composition including solid content and an organic solvent. The solid content may include a resin material including a material including a hydroxyl group, an acrylate-based material, and a material including a polycyclic group; a photosensitizer including a photo active compound (PAC); a plasticizer; an initiator; and a surfactant.

In one or more embodiments, an amount of the material including the hydroxyl group may be about 40 wt % to about 70 wt % relative to 100 wt % of the total weight of the solid content. An amount of the acrylate-based material may be about 1 wt % to about 20 wt % relative to 100 wt % of the total weight of the solid content. An amount of the material including the polycyclic group may be about 1 wt % to about 20 wt % relative to 100 wt % of the total weight of the solid content.

In one or more embodiments, the material including the hydroxyl group may include a material represented by Chemical Formula 6-1. The acrylate-based material may include a material represented by Chemical Formula 6-2. The material including the polycyclic group may include a material represented by Chemical Formula 6-3.

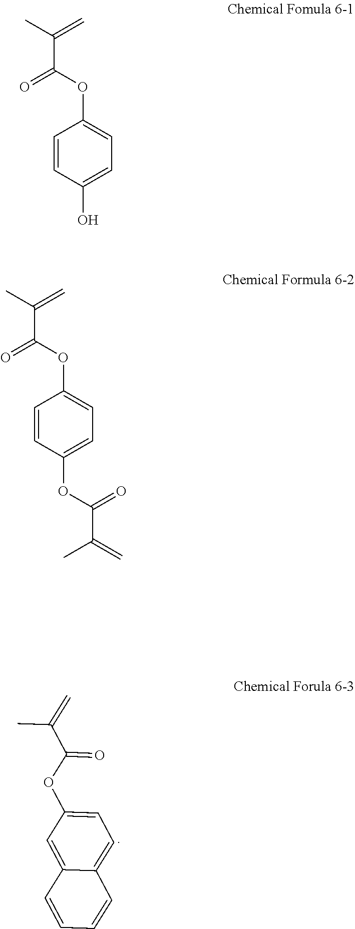

In one or more embodiments, an amount of the photosensitizer may be about 0.2 wt % to about 20 wt % relative to 100 wt % of the total weight of the solid content. An amount of the plasticizer may be about 0.1 wt % to about 10 wt % relative to 100 wt % of the total weight of the solid content. An amount of the initiator may be about 2 wt % to about 20 wt % relative to 100 wt % of the total weight of the solid content.

In one or more embodiments, the photosensitizer may include one or more selected from among a material represented by Chemical Formula 7-1, a material represented by Chemical Formula 7-2, and/or a material represented by Chemical Formula 7-3. The plasticizer may include a material represented by Chemical Formula 8. The initiator may include one or more selected from among a material represented by Chemical Formula 9-1, a material represented by Chemical Formula 9-2, a material represented by Chemical Formula 9-3, a material represented by Chemical Formula 9-4, a material represented by Chemical Formula 9-5, a material represented by Chemical Formula 9-6, and/or a material represented by Chemical Formula 9-7.

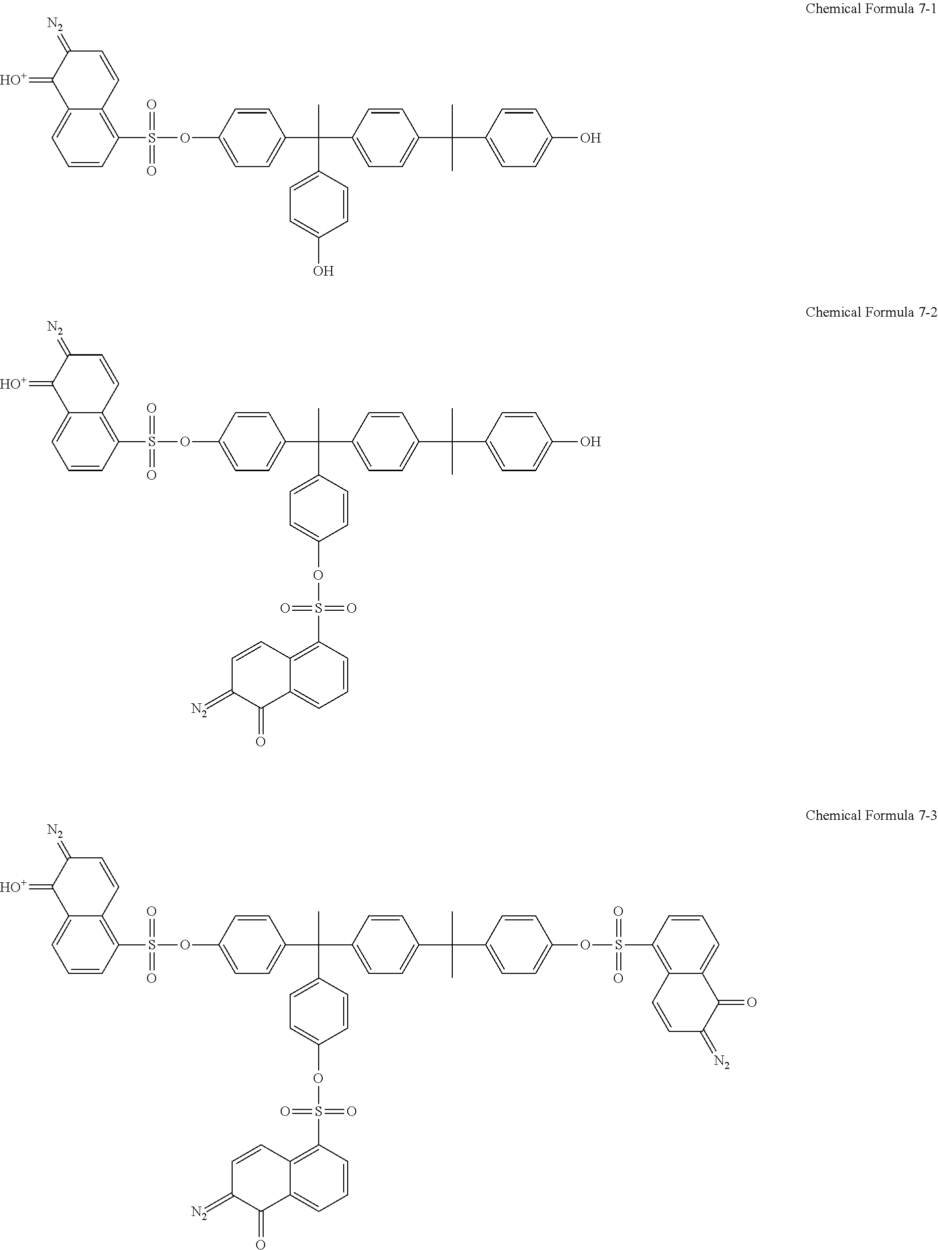

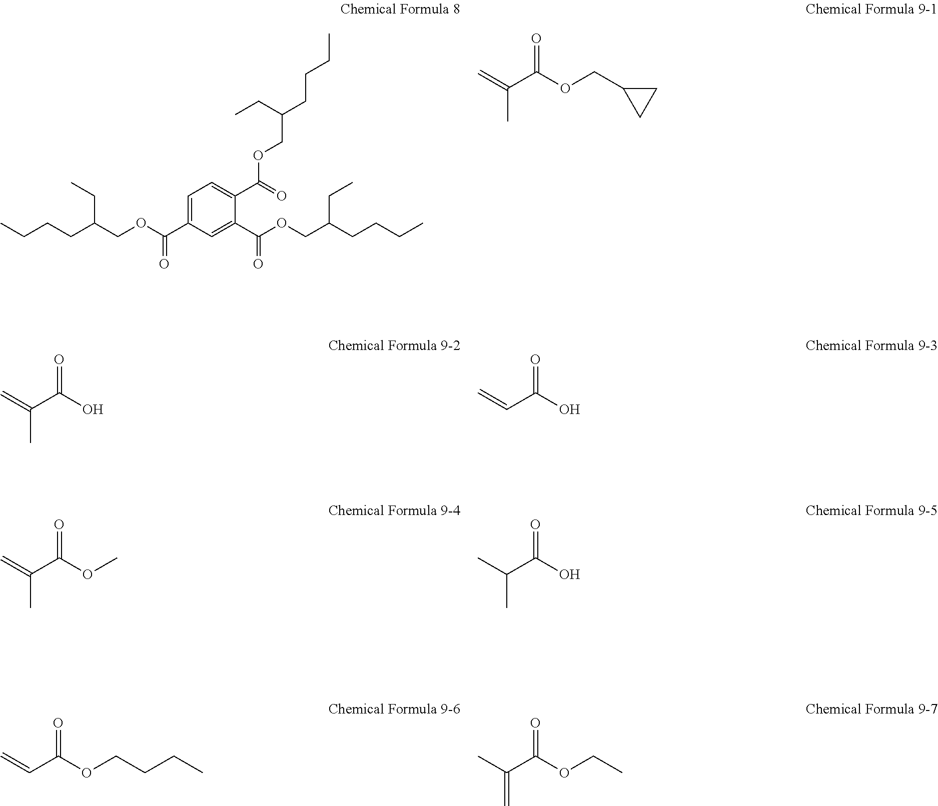

In one or more embodiments, the surfactant may include one or more selected from among a fluoro-based surfactant and/or a silicon-based surfactant.

In one or more embodiments, an amount of the surfactant may be about 0.05 wt % to about 3 wt % relative to 100 wt % of the total weight of the solid content of the photosensitive resin composition.

In one or more embodiments, the organic solvent may include propylene glycol monomethyl ether (PGME).

In one or more embodiments, an amount of the organic solvent may be about 60 wt % to 90 wt % relative to 100 wt % of the total weight of the photosensitive resin composition.

One or more embodiments of the present disclosure are directed towards a method for manufacturing a display device, including forming a display layer, and forming a lens layer on the display layer. Forming the lens layer may include forming a base lens layer including a resin composition for lenses, and patterning lenses by removing at least a portion of the base lens layer. The resin composition may include solid content and an organic solvent. The solid content may include a resin material including a carbazole-based material and an acrylate-based material; a multifunctional cross-linker; an initiator including a thermal initiator and a photoinitiator; and a sensitizer.

In one or more embodiments, forming the base lens layer may include performing a process of curing the base lens layer.

In one or more embodiments, forming the lens layer may further include forming a base photosensitive resin composition layer on the base lens layer, and patterning an etching mask by removing at least a portion of the base photosensitive resin composition layer. The base photosensitive resin composition layer may include solid content and an organic solvent. The solid content in the base photosensitive resin composition layer may include a resin material including a material including a hydroxyl group, an acrylate-based material, and a material including a polycyclic group; a photosensitizer including a photo active compound (PAC); a plasticizer; an initiator; and a surfactant.

In one or more embodiments, optionally, forming the lens layer may further include forming an interlayer insulating layer on the base lens layer before forming the base photosensitive resin composition layer.

In one or more embodiments, forming the lens layer may include directly patterning the base lens layer without forming a layer based on a photosensitive material on the base lens layer.

One or more embodiments of the present disclosure are directed towards a display device manufactured by the method. The display layer may include a silicon substrate, a light emitting element on the silicon substrate, and a color filter on the light emitting element. The lens layer may be on the color filter.

In one or more embodiments, the lens layer may have a thickness in a range from 2.7 μm to 3.3 μm.

According to some embodiments of the present disclosure, an electronic device, may comprising: a processor configured to provide input image data; a display device manufactured by the method and configured to display an image based on the input image data, the display device including sub-pixel areas; and a power supply configured to supply power to the display device.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic plan view illustrating a display device in accordance with one or more embodiments.

FIG. 2 is a schematic cross-sectional view illustrating a display device in accordance with one or more embodiments.

FIGS. 3-16 are diagrams each illustrating a method for manufacturing the display device in accordance with one or more embodiments.

FIG. 17 is a block diagram illustrating a electronic device in accordance with one or more embodiments.

FIG. 18 is a perspective diagram illustrating an application example of the electronic device of FIG. 17 in accordance with one or more embodiments.

FIG. 19 is a diagram illustrating a head-mounted display device of FIG. 18 that is worn on a user in accordance with one or more embodiments.

### DETAILED DESCRIPTION

Hereinafter, one or more embodiments of the present disclosure will be described in more detail with reference to the attached drawings. In the following description, only parts useful for understanding of operations in accordance with the present disclosure will be described, and explanation of the other parts may not be provided in an effort not to make the gist of the present disclosure unclear. Accordingly, the subject matter of the present disclosure is not limited to the embodiments set forth herein but may be embodied in other suitable forms. Rather, these embodiments are provided so that the present disclosure will be thorough and complete, and will fully convey the technical spirit of the disclosure to those skilled in the art.

In the present disclosure, the terminology utilized herein is utilized to describe embodiments only, and is not intended to limit the present disclosure. As used herein, the singular forms “a,” “an,” and “the” are intended to include the plural forms as well unless the context clearly dictates otherwise. Further, the utilization of “may” when describing embodiments of the present disclosure refers to “one or more embodiments of the present disclosure”. It will be understood that when an element is referred to as being “coupled” or “connected” to another element, it may be directly coupled or connected to the other element or intervening elements may be present therebetween. The terminology utilized herein is for the purpose of describing particular embodiments only and is not intended to be limiting. In the specification, when an element is referred to as “comprising,” “having,” or “including” a component, it does not preclude another component but may further include other components unless the context clearly indicates otherwise. As utilized herein, the term “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. For instance, “at least one of X, Y, and Z” and “at least one selected from the group consisting of X, Y, and Z” may be construed as X only, Y only, Z only, or any combination of two or more of X, Y, and Z (for instance, XYZ, XYY, YZ, and ZZ). The “/” utilized herein may be interpreted as “and” or as “or” depending on the situation. Although the terms “first,” “second,” etc. may be utilized herein to describe various types (or kinds) of elements, these elements should not be limited by these terms. These terms are utilized to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be utilized herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” may encompass both an orientation of above and below. Furthermore, the device may be otherwise oriented (e.g., rotated 90 degrees or at other orientations), and, as such, the spatially relative descriptors utilized herein are interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting. In the drawings, thicknesses of some components may be exaggerated for effectively explaining the technical contents. Like reference numerals refer to like elements throughout, and duplicative descriptions thereof may not be provided the specification.

In one or more embodiments of the present disclosure, if (e.g., when) a functional group part is stated without specifying whether it is a substituted part or a non-substituted part, the functional group part may include both a functional group having no substituent and a functional group having a substituent.

In one or more embodiments of the present disclosure, unless specifically mentioned otherwise, a viscosity value represents a viscosity value measured at 25° C.

In one or more embodiments of the present disclosure, unless specifically mentioned otherwise, a refractive index value for a target material is a refractive index value for light having a wavelength of 400 nm.

In one or more embodiments of the present disclosure, the compounds described in relation to each composition may be synthesized utilizing any suitable process generally utilized in the art, and in some cases, commercially available products may be utilized.

In one or more embodiments of the present disclosure, the content (e.g., an amount, such as a molar content) of a target material included in solid content may be measured in various suitable ways. For example, the content (e.g., amount) of the target material may be measured/analyzed by capillary gas chromatography, liquid chromatography, gel permeation chromatography, and/or the like.

Various embodiments of the present disclosure relate to a resin composition for lenses, a photosensitive resin composition, a method for manufacturing a display device including a lens, a display device including a lens, and an electronic device comprising the display device. Hereinafter, a resin composition for lenses, a photosensitive resin composition, a method for manufacturing a display device including a lens, a display device including a lens, and an electronic device comprising the display device in accordance with embodiments will be described with reference to the accompanying drawings.

### 1. Display Device

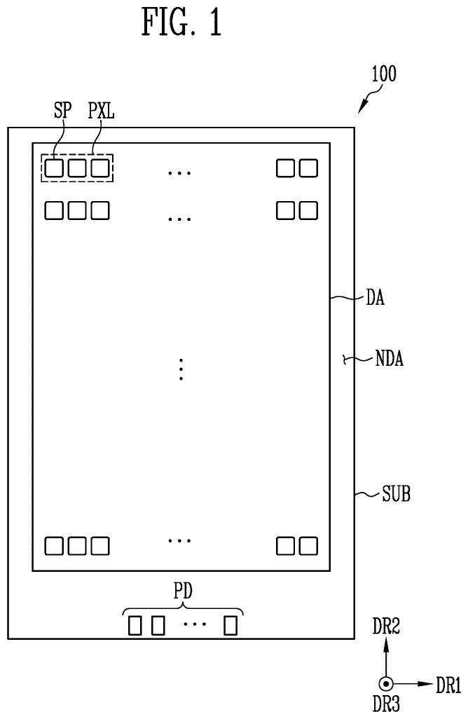

FIG. 1 is a schematic plan view illustrating a display device 100 in accordance with one or more embodiments of the present disclosure.

In one or more embodiments, referring to FIG. 1, the display device 100 may be configured to emit light, e.g., the display device 100 may be utilized to emit light.

The display device 100 may include a display area DA and a non-display area NDA. The display device 100 may display an image through the display area DA. The non-display area NDA may be provided around the display area DA.

The display device 100 may include a substrate SUB, sub-pixels SP, and pads PD.

In some embodiments, the display device 100 may be utilized as a display screen for a head mounted display (HMD), a virtual reality (VR) device, a mixed reality (MR) device, an augmented reality (AR) device, and/or the like. The display device 100 may be provided very close to the eyes of the user. In some embodiments, relatively high-density sub-pixels SP may be utilized or required. To increase the pixel density of the sub-pixels SP, the substrate SUB may be provided utilizing a silicon substrate. The sub-pixels SP may be formed on the substrate SUB that is formed of a silicon substrate. The display device 100 including a plurality of layers on the substrate SUB that includes a silicon substrate may be referred to as an OLED on Silicon (OLEDoS) display device.

The sub-pixels SP may be in the display area DA on the substrate SUB. The sub-pixels SP may be in the form of a matrix (e.g., a matrix structure) along a first direction DR1 and a second direction DR2 intersecting with the first direction DR1. However, the embodiments are not limited to the aforementioned embodiments. For example, the sub-pixels SP may be in a zigzag pattern (e.g., a pattern of a skew apeirogon) in the first direction DR1 and the second direction DR2. For example, the sub-pixels SP may be in the form of a PENTILE® arrangement structure (e.g., an RGBG matrix, RGBG structure, or RGBG matrix structure), but the present disclosure is not limited thereto. PENTILE® is a duly registered trademark of Samsung Display Co., Ltd.

The first direction DR1 may refer to a row direction, and the second direction DR2 may refer to a column direction.

The plane of the present disclosure may extend in the first direction DR1 and the second direction DR2, and may be defined based on the plane on which the substrate SUB is. In one or more embodiments, the third direction DR3 may correspond to a thickness direction of the substrate SUB. The third direction DR3 may correspond to a light output direction of the display device 100.

The sub-pixels SP may each have various suitable shapes in a plan view. The shape of each of the sub-pixels SP is not limited to a specific embodiment.

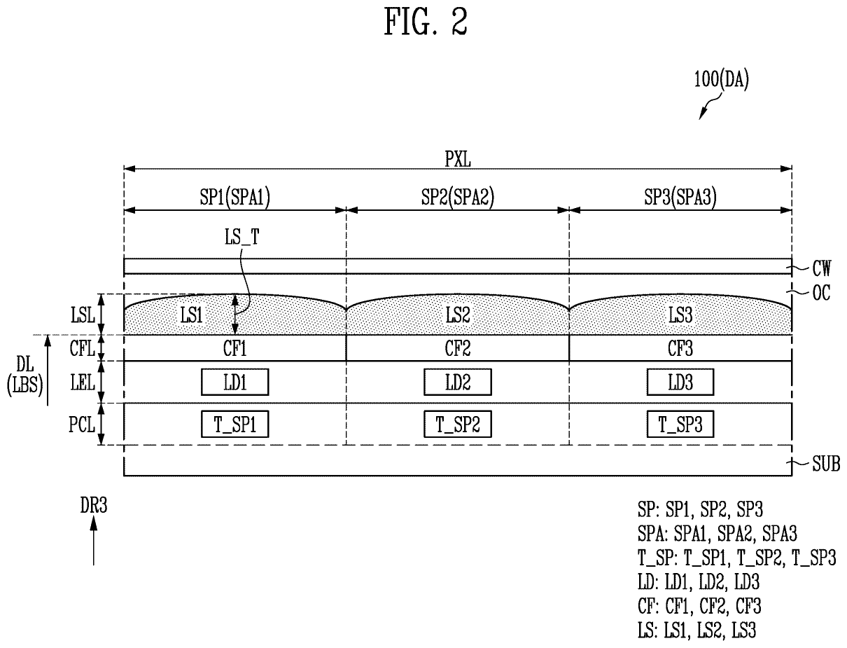

Each of the sub-pixels SP may include at least one light emitting element LD (refer to FIG. 2) configured to generate light (e.g., the light emitting element LD may be utilized to generate light). Accordingly, each of the sub-pixels SP may generate light in a set or specific color, such as red, green, blue, cyan, magenta, and/or yellow. Two or more sub-pixels SP among the sub-pixels SP may form one pixel PXL. For example, as illustrated in FIG. 1, three sub-pixels SP may form one pixel PXL.

Hereinafter, descriptions will be provided based on one or more embodiments where the sub-pixels SP include a first sub-pixel SP1 configured to provide light of a first color (e.g., red), a second sub-pixel SP2 configured to provide light of a second color (e.g., green), and a third sub-pixel SP3 configured to provide light of a third color (e.g., blue).

In one or more embodiments, the first sub-pixel SP1 may provide light in a wavelength band in a range from 600 nm to 750 nm as a red pixel. The second sub-pixel SP2 may provide light in a wavelength band in a range from 480 nm to 560 nm as a green pixel. The third sub-pixel SP3 may provide light in a wavelength band in a range from 370 nm to 460 nm as a blue pixel.

Components for controlling the sub-pixels SP may be in the non-display area NDA on the substrate SUB. For example, lines connected to the sub-pixels SP (e.g., gate lines and data lines for driving the sub-pixels SP) may be in the non-display area NDA. Furthermore, a gate driver, a data driver, a voltage generator, a controller, a temperature sensor, and/or the like may be integrated in the non-display area NDA of the display device 100 to acquire driving signals to be supplied to the sub-pixels SP. However, the present disclosure is not limited to the aforementioned embodiment.

The pads PD may be in the non-display area NDA on the substrate SUB. The pads PD may be electrically connected to the sub-pixels SP through the lines. For example, the pads PD may be connected to the sub-pixels SP through the data lines.

The pads PD may interface the components in the display area DA and the non-display area NDA with other components of the display device 100. In embodiments, voltages and signals utilized or required for the operation of the components included in the display device 100 may be provided from a driver integrated circuit through the pads PD. For example, the data lines may be electrically connected to the driver integrated circuit through the pads PD. For example, the power voltages for driving the sub-pixels SP may be received from the driver integrated circuit through the pads PD. For example, a gate control signal that controls the gate driver may be transmitted from the driver integrated circuit to the gate driver through the pads PD.

In embodiments, a circuit board may be electrically connected to the pads PD by a conductive adhesive component (e.g., an electrically conductive adhesive component) such as an anisotropic conductive film. Here, the circuit board may be a flexible circuit board or flexible film that is made of flexible material. The driver integrated circuit may be mounted on the circuit board and be electrically connected to the pads PD.

In embodiments, the display area DA may have various suitable shapes. The display area DA may have a closed-loop shape, including linear and/or curved sides. For example, the display area DA may have shapes such as a polygon, a circle, a semicircle, and/or an ellipse.

In embodiments, the display device 100 may have a planar display surface. In embodiments, the display device 100 may have a display surface that is at least partially rounded. In embodiments, the display device 100 may be bendable, foldable, and/or rollable. In the aforementioned cases, the display device 100 and/or the substrate SUB may include materials having flexible properties.

FIG. 2 is a schematic sectional view illustrating the display device 100 in accordance with one or more embodiments. FIG. 2 schematically illustrates a cross-sectional structure of the first to third sub-pixels SP1 to SP3 in the display area DA.

In one or more embodiments, referring to FIG. 2, the display device 100 may include a display layer DL, a lens layer LSL, an overcoat layer OC, and a cover window CW.

In one or more embodiments, the display layer DL may include a substrate SUB, a pixel circuit layer PCL, a light-emitting-element layer LEL, and a color filter layer CFL.

In one or more embodiments, the pixel PXL may be formed in the display area DA. The sub-pixels SP may include a first sub-pixel SP1 configured to provide light of a red color, a second sub-pixel SP2 configured to provide light of a green color, and a third sub-pixel SP3 configured to provide light of a blue color. The sub-pixels SP may form a sub-pixel area SPA formed to provide a color of light. The sub-pixel area SPA may include a first sub-pixel area SPA1 formed to provide light of a red color, a second sub-pixel area SPA2 formed to provide light of a green color, and a third sub-pixel area SPA3 formed to provide light of a blue color.

In one or more embodiments, the substrate SUB may include a silicon wafer substrate formed through a semiconductor process. The substrate SUB may include semiconductor material suitable to form circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, and/or the like. In one or more embodiments, the substrate SUB may include a glass substrate. In one or more embodiments, the substrate SUB may include a polyimide substrate.

In one or more embodiments, the pixel circuit layer PCL may be on the substrate SUB. The pixel circuit layer PCL may include circuit elements including one or more transistors T_SP, and one or more capacitors. In one or more embodiments, the transistor T_SP may include a first transistor T_SP1 configured to drive the light emitting element LD of the first sub-pixel SP1, a second transistor T_SP2 configured to drive the light emitting element LD of the second sub-pixel SP2, and a third transistor T_SP3 configured to drive the light emitting element of the third sub-pixel SP3.

In one or more embodiments, the light-emitting-element layer LEL may be on the pixel circuit layer PCL. The light-emitting-element layer LEL may include light emitting elements LD, an anode electrode and a cathode electrode that are electrically connected to the light emitting elements LD, and an insulating layer (e.g., an electrically insulating layer) adjacent to the light emitting elements LD (e.g., a pixel defining layer and/or the like). Each of the light emitting elements LD may include an organic light emitting diode. For example, the light emitting elements LD may each include an emission layer configured to generate light, an electron transport layer configured to transport electrons, and a hole transport layer configured to transport holes. In one or more embodiments, the light emitting elements LD may include a first light emitting element LD1 included in the first sub-pixel SP1, a second light emitting element LD2 included in the second sub-pixel SP2, and/or a third light emitting element LD3 included in the third sub pixel SP3.

The color filter layer CFL may be on the light-emitting-element layer LEL. In one or more embodiments, the color filter layer CFL may include color filters CF each of which allows light of one color to selectively pass therethrough. For example, the color filters CF may each include a dye and/or pigment that allows light of one color to selectively pass therethrough. The color filters CF may include a first color filter CF1 included in the first sub-pixel SP1 and configured to allow red light corresponding to the first sub-pixel SP1 to pass therethrough, a second color filter CF2 included in the second sub-pixel SP2 and configured to allow green light corresponding to the second sub-pixel SP2 to pass therethrough, and/or a third color filter CF3 included in the third sub-pixel SP3 and configured to allow blue light corresponding to the third sub-pixel SP3 to pass therethrough.

The lens layer LSL may be on the display layer DL (e.g., the color filter layer CFL). In one or more embodiments, the display layer DL may form a base on which the lens layer LSL is. The display layer DL may be a lens base layer LBS.

The lens layer LSL may include lenses LS. In one or more embodiments, the lenses LS may include a first lens LS1 in the first sub-pixel area SPA1 and included in the first sub-pixel SP1, a second lens LS2 in the second sub-pixel area SPA2 and included in the second sub-pixel SP2, and/or a third lens LS3 in the third sub-pixel area SPA3 and included in the third sub-pixel SP3.

The lenses LS may output light provided from the light emitting elements LD in a suitable or desired path, and enhance light output efficiency of the display device 100.

The lenses LS may have a relatively high refractive index. For example, the lenses LS may have a higher refractive index than the overcoat layer OC.

In one or more embodiments, the lenses LS may have a lens thickness LS_T. The lens thickness LS_T may have a relatively large thickness. For example, the lens thickness LS_T may range from approximately 2.7 μm to approximately 3.3 μm. For example, the lens thickness LS_T may range from approximately 2.9 μm to approximately 3.1 μm.

The lens thickness LS_T may be defined based on a display direction of the display device 100. The lens thickness LS_T may be defined based on the thickness direction of the substrate SUB (e.g., the third direction DR3).

In one or more embodiments, light provided from the light emitting elements LD may be refracted on upper surfaces of the lenses LS and provided out of the display device 100. Accordingly, a light path may be defined substantially along the display direction of the display device 100 (e.g., the third direction DR3).

In one or more embodiments, the lenses LS may be manufactured utilizing a resin composition for lenses.

In one or more embodiments, the lens LS manufactured based on the resin composition for lenses may have high refractive characteristics. Accordingly, a total reflection may occur between layers formed in the display device 100, thereby further reducing the risk of light loss and enhancing the light output efficiency of the display device 100.

In one or more embodiments, the resin composition for lenses may have a set or certain viscosity range. Accordingly, if (e.g., when) lenses LS are manufactured utilizing the resin composition for lenses in accordance with one or more embodiments, each of the lenses LS may be formed to have the aforementioned lens thickness LS_T (e.g., approximately 2.7 μm to approximately 3.3 μm, or for example, approximately 2.9 μm to approximately 3.1 μm).

The resin composition for lenses in accordance with one or more embodiments may have excellent chemical resistance. Therefore, if (e.g., when) a process of patterning the lenses LS utilizing the resin composition for lenses is performed, the risk of both materials (e.g., the photosensitive resin material and the resin material) being intermixed at an interface between the lenses LS and a photosensitive resin composition layer formed on the lenses LS may be reduced.

Detailed description pertaining to the resin composition for lenses in accordance with an embodiment will now be made in more detail.

The overcoat layer OC may be on the lens layer LSL. The overcoat layer OC may cover the other layers under the overcoat layer OC, and may include various suitable materials suitable to protect the other layers from foreign substances, such as dust and water. For example, the overcoat layer OC may include at least one selected from among an inorganic insulating layer (e.g., an inorganic electrically insulating layer) and/or an organic insulating layer (e.g., an organic electrically insulating layer). For instance, the overcoat layer OC may include epoxy, but the embodiments are not limited thereto.

The cover window CW may be on the overcoat layer OC. The cover window CW may protect the other layers under the cover window CW. The cover window CW may include glass material. However, the present disclosure is not limited to the embodiment. In one or more embodiments, the cover window CW may be formed of encapsulation glass. In some embodiments, the cover window CW may be omitted.

### 2. Resin Composition for Lenses

Hereinafter, a resin composition for lenses utilized to manufacture the lens LS in accordance with one or more embodiments will be further described.

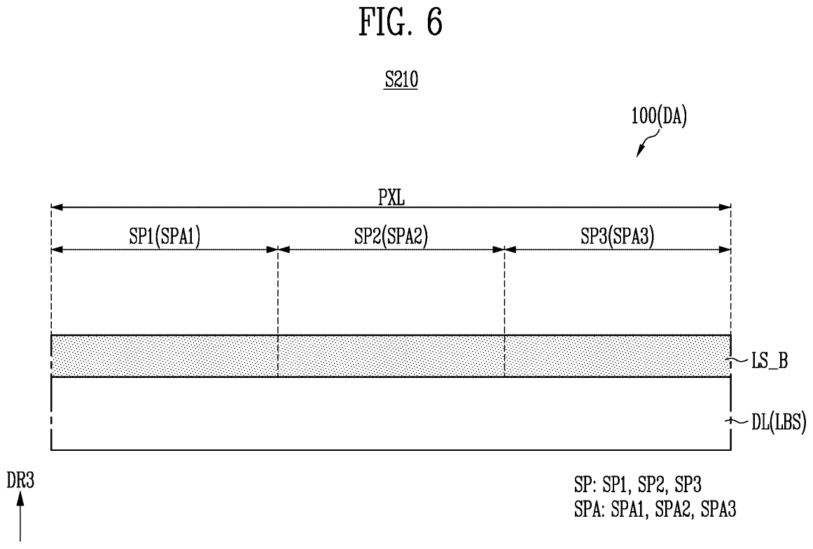

In one or more embodiments, a layer (e.g., a base lens layer LS_B referring to FIG. 6) formed to manufacture the lens LS may include a resin composition for lenses.

In one or more embodiments, the resin composition for lenses may include (A) a resin material, (B) a cross-linker, (C) an initiator, (D) a sensitizer, and/or (E) a solvent.

In one or more embodiments, materials in the resin composition for lenses, except for the solvent, may be defined as solid content. For example, the solid content of the resin composition for lenses may include (A) the resin material, (B) the cross-linker, (C) the initiator, and (D) the sensitizer.

### (a) Resin Material

The resin material may be a primary component of the solid content in the resin composition for lenses, enabling the lens LS to have high refractive characteristics. In one or more embodiments, if (e.g., when) the resin composition for lenses is cured, the lens LS may have relatively high refractive characteristics.

In one or more embodiments, the resin material may include a moiety (e.g., a set specific group of atoms within a molecule that is responsible for characteristic chemical reactions of the molecule) to achieve high refractive characteristics. In one or more embodiments, the resin material may include a carbazole-based material and/or an acrylate-based material.

The carbazole-based material may include poly(9-vinylcarbazole) represented by the following Chemical Formula 1-1.

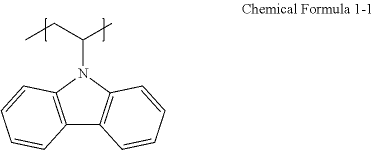

In one or more embodiments, if (e.g., when) the resin material includes a carbazole-based material (e.g., poly-vinylcarbazole, or poly(9-vinylcarbazole)), the lens LS may have excellent high refractive characteristics. For example, poly(9-vinylcarbazole) may have a refractive index of approximately 1.68. Accordingly, the lens LS provided after the base lens layer LS_B is cured may have a relatively high refractive index (e.g., a refractive index of 1.6 or higher).

Furthermore, in one or more embodiments, if (e.g., when) the resin material includes a carbazole-based material (e.g., poly-vinylcarbazole, and/or poly(9-vinylcarbazole)), the lens LS may have improved heat resistance and transmittance properties (e.g., light transmittance properties).

Furthermore, in one or more embodiments, if (e.g., when) the resin material includes a carbazole-based material (e.g., poly-vinylcarbazole, and/or poly(9-vinylcarbazole)), the resin composition for lenses may have excellent chemical resistance. Therefore, if (e.g., when) a photosensitive resin material layer is formed to pattern the lens LS, the risk of both materials (e.g., photosensitive resin material and the resin material) being intermixed at an interface between a layer related to the resin composition for lenses (e.g., the base lens layer LS_B) and the photosensitive resin material layer may be reduced.

Furthermore, in one or more embodiments, if (e.g., when) the resin material includes a carbazole-based material (e.g., poly-vinylcarbazole, and/or poly(9-vinylcarbazole)), the resin composition for lenses may have excellent heat resistance.

In one or more embodiments, if (e.g., when) the resin material includes a carbazole-based material (e.g., poly-vinylcarbazole, and/or poly(9-vinylcarbazole)), the lens LS provided after the base lens layer LS_B is cured may have excellent light transmittance.

The acrylate-based material may include benzyl methacrylate represented by the following Chemical Formula 1-2.

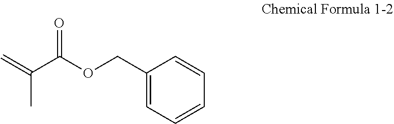

In one or more embodiments, if (e.g., when) the resin material includes an acrylate-based material (e.g., benzyl methacrylate), the lens LS may have relatively suitable or satisfactory durability while securing suitable or sufficient high refractive characteristics. For example, the benzyl methacrylate may have a refractive index of approximately 1.57. Accordingly, the lens LS provided after the base lens layer LS_B (refer to FIG. 6) is cured may have a relatively high refractive index, and may have suitable or satisfactory durability.

Furthermore, in one or more embodiments, if (e.g., when) the resin material include an acrylate-based material (e.g., benzyl methacrylate), the development properties of the resin composition for lenses may be enhanced.

In one or more embodiments, the resin material may have a refractive index in a range from about 1.55 to about 1.75 for light having a wavelength of 400 nm. The resin material may have a refractive index in a range from about 1.6 to about 1.68 for light having a wavelength of 400 nm. For example, the resin material may have a refractive index of approximately 1.64 for light having a wavelength of 400 nm. In one or more embodiments, if (e.g., when) the aforementioned numerical range (e.g., the refractive index range from about 1.55 to about 1.75, or for example, from about 1.6 to about 1.68) is satisfied, the path of light emitted from the light emitting element LD in the display device 100 may be properly defined in the lens LS provided by curing the base lens layer LS_B.

In one or more embodiments, the resin material may include materials including moieties for achieving various high refractive characteristics, as well as carbazole-based materials and acrylate-based materials.

For example, in one or more embodiments, the resin material may include a cardo-based material. The resin material may include a compound represented by the following Chemical Formula 1-3. In one or more embodiments, the resin material may include bisphenol-A-Epoxy represented by the following Chemical formula 1-4. In one or more embodiments, the resin material may include 4-hydroxyphenyl methacrylate by the following Chemical formula 1-5. In one or more embodiments, the resin material may include 1,4-phenylene bis(2-methylacrylate) represented by the following Chemical Formula 1-6. In one or more embodiments, the resin material may include a hydrocarbon including a polycyclic group represented by the following Chemical Formula 1-7. In one or more embodiments, the resin material may include a hydrocarbon including a polycyclic group represented by the following Chemical Formula 1-8. In one or more embodiments, the resin material may include a hydrocarbon including a polycyclic group represented by the following Chemical Formula 1-9. In one or more embodiments, the resin material may include an organic/inorganic composite represented by the following Chemical Formula 1-10.

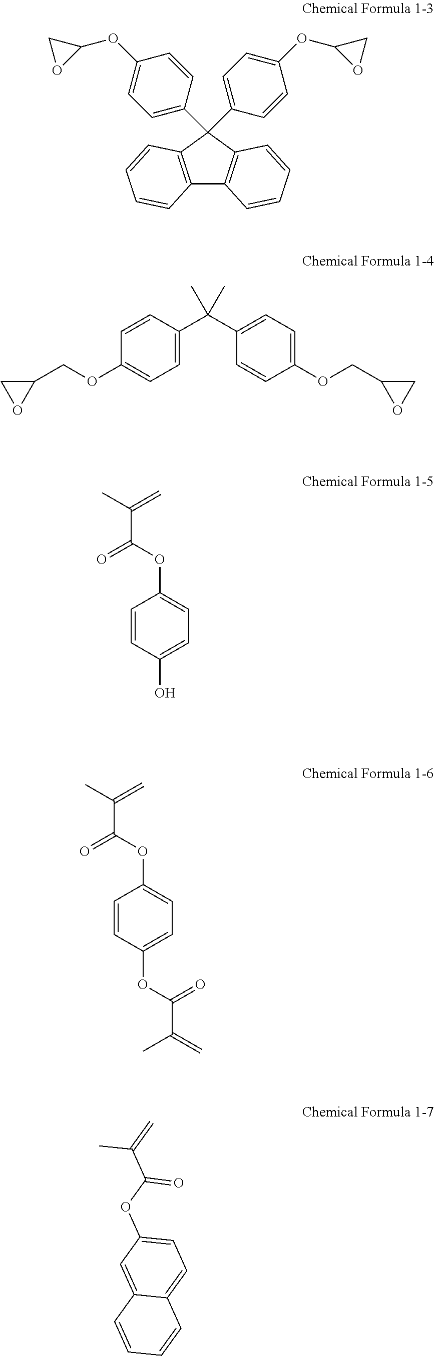 [SMILES: c1ccc2c(c1)-c1ccccc1C2(c1ccc(OC2CO2)cc1)c1ccc(OC2CO2)cc1 ; CC(C)(c1ccc(OCC2CO2)cc1)c1ccc(OCC2CO2)cc1 ; C=C(C)C(=O)Oc1ccc(O)cc1 ; C=C(C)C(=O)Oc1ccc(OC(=O)C(=C)C)cc1 ; C=C(C)C(=O)Oc1ccc2ccccc2c1]

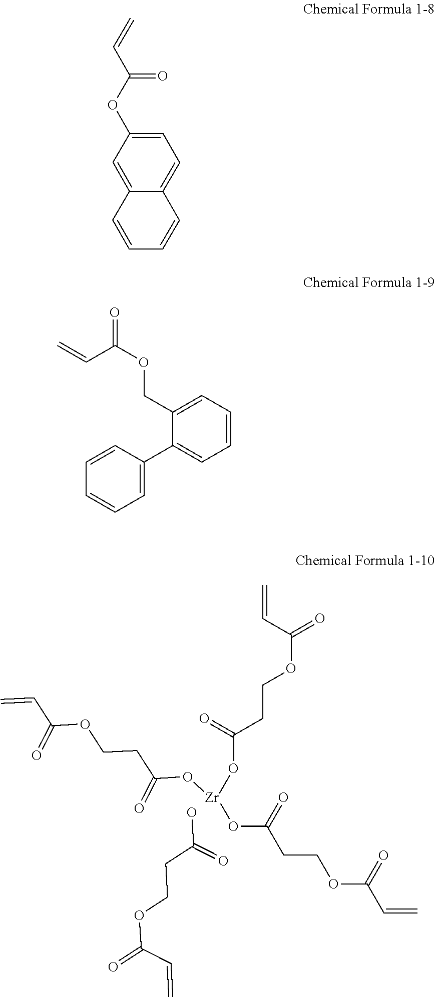

In one or more embodiments, an amount of the resin material may be about 76 wt % (weight %) to about 98.2 wt % relative to 100 wt % of a total weight of the solid content of the resin composition for lenses. For example, in some embodiments, the resin material may include a carbazole-based material and/or an acrylate-based material, an amount of the carbazole-based material may be about 75 wt % to about 95 wt % relative to 100 wt % of a total weight of the solid content of the resin composition for lenses, while an amount of the acrylate-based material may be about 1 wt % to about 15 wt % relative to 100 wt % of a total weight of the solid content of the resin composition for lenses. In some embodiments, if (e.g., when) the aforementioned numerical range (e.g., the amount of the carbazole-based material being about 75 wt % to about 95 wt % and/or the amount of the acrylate-based material being about 1 wt % to about 15 wt %, relative to 100 wt % of a total weight of the solid content of the resin composition for lenses) is satisfied, the resin composition for lenses may have excellent high refractive characteristics, heat resistance, and transmittance (e.g., light transmittance), and may have relatively excellent durability.

### (B) Cross-Linker

The cross-linker may enable the lens LS to have a more robustly cured structure if (e.g., when) the resin composition for lens is cured. In one or more embodiments, the cross-linker in accordance with an embodiment may be a multifunctional cross-linker.

In one or more embodiments, the cross-linker may include one or more of multifunctional cross-linkers represented by the following Chemical Formula 2-1 and/or the following Chemical Formula 2-2. In one or more embodiments, if (e.g., when) the cross-linker includes one or more of the multifunctional cross-linkers, the degree of cross-linking in the resin composition for lenses may be improved.

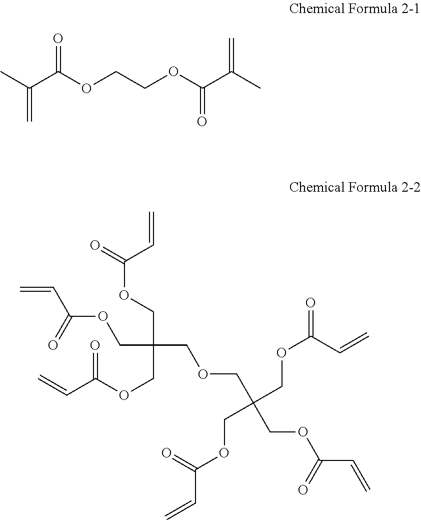

In one or more embodiments, an amount of the cross-linker may be about 1 wt % to about 15 wt % relative to 100 wt % of a total weight of the solid content of the resin composition for lenses. For example, an amount of the multifunctional cross-linker according to the foregoing Chemical Formula 2-1 may be about 1 wt % to about 15 wt % relative to 100 wt % of a total weight of the solid content of the resin composition for lenses. In some embodiments, an amount of the multifunctional cross-linker according to the foregoing Chemical Formula 2-2 may be about 1 wt % to about 15 wt % relative to 100 wt % of a total weight of the solid content of the resin composition for lenses. In some embodiments, an amount of the multifunctional cross-linker according to the foregoing Chemical Formula 2-1 and an amount of the multifunctional cross-linker according to the foregoing Chemical Formula 2-2 may be about 1 wt % to about 15 wt % relative to 100 wt % of a total weight of the solid content of the resin composition for lenses. For example, the sum of the respective contents (e.g., amounts) of the multifunctional cross-linker according to the foregoing Chemical Formula 2-1 and the multifunctional cross-linker according to the foregoing Chemical Formula 2-2 may be about 1 wt % to about 15 wt % relative to 100 wt % of a total weight of the solid content of the resin composition for lenses.

### (C) Initiator

The initiator may be provided to initiate polymerization of the resin composition for lenses. The initiator may include a plurality of initiators. For example, the initiator may include a thermal initiator and a photoinitiator. In one or more embodiments, the initiator may include a thermal initiator and a photoinitiator, so that the resin composition for lenses may have excellent cross-linking characteristics.

In one or more embodiments, the thermal initiator may include a nitrile-based compound. For example, the thermal initiator may include a material represented by the following Chemical Formula 3-1. The photoinitiator may include an oxime-based compound. For example, the photoinitiator may include a material represented by the following Chemical Formula 3-2 and/or a material represented by the following Chemical Formula 3-3.

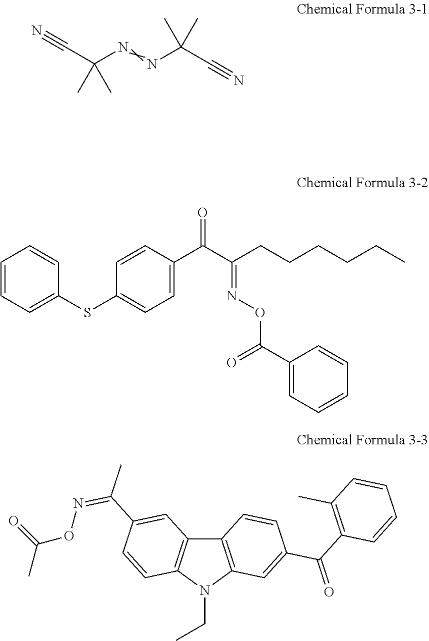 [SMILES: CC(C)(C#N)N=NC(C)(C)C#N ; CCCCCC/C(=N\OC(=O)c1ccccc1)C(=O)c1ccc(Sc2ccccc2)cc1 ; CCn1c2ccc(/C(C)=N\OC(C)=O)cc2c2ccc(C(=O)c3ccccc3C)cc21]

In one or more embodiments, an amount of the thermal initiator may be about 0.5 wt % to about 5 wt % relative to 100 wt % of a total weight of the solid content of the resin composition for lenses. In one or more embodiments, an amount of the photoinitiator may be about 0.1 wt % to about 10 wt % relative to 100 wt % of a total weight of the solid content of the resin composition for lenses.

In one or more embodiments, the initiator may further include an auxiliary initiator. For example, the auxiliary initiator may be a relatively small amount in the resin composition for lenses compared to the initiator in the resin composition for lenses.

In one or more embodiments, the auxiliary initiator may include a material including a hydroxyl group.

For example, the auxiliary initiator may include one or more selected from among a material represented by the following Chemical Formula 4-1, a material represented by the following Chemical Formula 4-2, a material represented by the following Chemical Formula 4-3, a material represented by the following Chemical Formula 4-4, and/or a material represented by the following Chemical Formula 4-5. For example, the auxiliary initiator may include a material represented by the following Chemical Formula 4-1 and a material represented by the following Chemical Formula 4-2. In one or more embodiments, the auxiliary initiator may further include a material represented by the following Chemical Formula 4-3, a material represented by the following Chemical Formula 4-4, and/or a material represented by the following Chemical Formula 4-5.

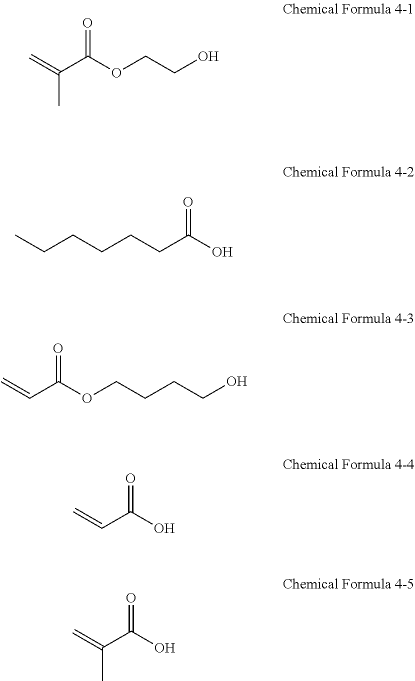

In one or more embodiments, an amount of the auxiliary initiator may be about 0.1 wt % to about 22.3 wt % relative to 100 wt % of a total weight of the solid content of the resin composition for lenses. For example, the auxiliary initiator may include one or more selected from among a material according to Chemical Formula 4-1, a material according to Chemical Formula 4-2, a material according to Chemical Formula 4-3, a material according to Chemical Formula 4-4, and/or a material according to Chemical Formula 4-5. In some embodiments, if (e.g., when) the material according to Chemical Formula 4-1 is included, an amount of the material according to Chemical Formula 4-1 may be about 0.2 wt % to about 10 wt % relative to 100 wt % of the total weight of the solid content of the resin composition for lenses. In some embodiments, if (e.g., when) the material according to Chemical Formula 4-2 is included, an amount of the material according to Chemical Formula 4-2 may be about 0.2 wt % to about 10 wt % relative to 100 wt % of the total weight of the solid content of the resin composition for lenses. In some embodiments, if (e.g., when) the material according to Chemical Formula 4-3 is included, an amount of the material according to Chemical Formula 4-3 may be about 0.1 wt % to about 5 wt % relative to 100 wt % of the total weight of the solid content of the resin composition for lenses. In some embodiments, if (e.g., when) the material according to Chemical Formula 4-4 is included, an amount of the material according to Chemical Formula 4-4 may be about 0.1 wt % to about 10 wt % relative to 100 wt % of the total weight of the solid content of the resin composition for lenses. In some embodiments, if (e.g., when) the material according to Chemical Formula 4-5 is included, the material according to Chemical Formula 4-5 may be included in an amount of 1 wt % to 10 wt % relative to 100 wt % of the total weight of the solid content of the resin composition for lenses. In some embodiments, if (e.g., when) the auxiliary initiator includes the material according to Chemical Formula 4-1 and the material according to Chemical Formula 4-2, an amount of the material according to Chemical Formula 4-1 may be about 0.2 wt % to about 10 wt % relative to 100 wt % of the total weight of the solid content of the resin composition for lenses, and an amount of the material according to Chemical Formula 4-2 may be about 0.2 wt % to about 10 wt % relative to 100 wt % of the total weight of the solid content of the resin composition for lenses.

### (D) Sensitizer

The sensitizer may be provided to catalyze polymerization of the resin composition for lenses. In one or more embodiments, the sensitizer may be a photosensitizer.

In one or more embodiments, the sensitizer may include an amine-based material. For example, the sensitizer may include one or more selected from among a material represented by the following Chemical Formula 5-1 and/or a material represented by the following Chemical Formula 5-2.

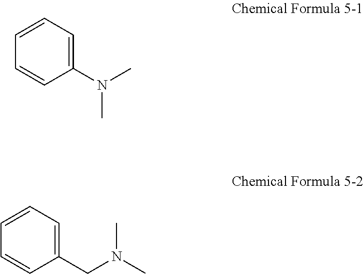

In one or more embodiments, an amount of the sensitizer may be about 0.1 wt % to about 5 wt % relative to 100 wt % of a total weight of the solid content of the resin composition for lenses.

### (E) Solvent

The solvent may include various suitable solvent materials, which may provide (e.g., taking into account) the dispersibility of the resin composition for lenses and the solubility of the materials forming the resin composition.

In one or more embodiments, the solvent may include an organic solvent. For example, the solvent may include one or more selected from among propylene glycol monomethyl ether (PGME) and/or propylene glycol methyl ether acetate (PGMEA).

In one or more embodiments, an amount of the solvent may be about 60 wt % to about 90 wt % relative to 100 wt % of a total weight of the resin composition for lenses. In some embodiments, if (e.g., when) the aforementioned numerical range (e.g., the amount of the solvent being about 60 wt % to about 90 wt % relative to 100 wt % of the total weight of the resin composition for lenses) is satisfied, the resin composition for lenses may have a viscosity in a range from about 10 cP to about 30 cP.

In one or more embodiments, if (e.g., when) the lens LS is manufactured utilizing the resin composition for lenses, the lens LS may be patterned to have a suitable or sufficient thickness. For example, to allow the lens LS of the display device 100 to have suitably or sufficiently high refractive characteristics, it may be suitable or desirable for the lens LS to have a relatively large thickness (e.g., lens thickness LS_T). In one or more embodiments, the solvent may be included in an amount corresponding to the aforementioned numerical range with respect to the resin composition for lenses (e.g., the amount of the solvent being about 60 wt % to about 90 wt % relative to 100 wt % of the total weight of the resin composition for lenses), thus enabling the viscosity of the resin composition for lenses to increase to have the foregoing viscosity range. Accordingly, the resin composition for lenses may be formed with a suitable or sufficient thickness to allow the lens LS to have suitably or sufficiently high refractive characteristics.

### 3. Photosensitive Resin Composition

Hereinafter, a photosensitive resin composition for lenses applicable to a process of manufacturing the lens LS in accordance with one or more embodiments will be described.

In one or more embodiments, a method for manufacturing the display device 100 may include a process of patterning the lens LS. In one or more embodiments, the photosensitive resin composition for manufacturing an etching mask PR_EM may be provided if (e.g., when) the lens LS is patterned.

In one or more embodiments, the photosensitive resin composition may include (A) a resin material, (B) a photosensitizer, (C) a plasticizer, (D) an initiator, (E) a surfactant, and/or (F) a solvent.

In one or more embodiments, materials included in the photosensitive resin composition except the solvent (e.g., excluding the solvent) may be defined/considered as solid content. For example, in one or more embodiments, the solid content of the photosensitive resin composition may include (A) the resin material, (B) the photosensitizer, (C) the plasticizer, (D) the initiator, and (E) the surfactant.

### (a) Resin Material

The resin material may be a primary material of the solid contents included in the photosensitive resin composition, and may improve development characteristics, cross-linking characteristics, and resolution of the photosensitive resin composition. In one or more embodiments, if (e.g., when) the photosensitive resin composition is utilized, process characteristics related to the development characteristics, the cross-linking characteristics, and the resolution may be improved.

In one or more embodiments, the resin material may include a material including a moiety to achieve improved development characteristics. For example, the resin material may include a material including a hydroxyl group (e.g., the moiety).

In one or more embodiments, the resin material may include a material including a moiety to achieve an improved degree of cross-linking. For example, the resin material may include an acrylate-based material (e.g., the moiety).

In one or more embodiments, the resin material may include a material including a moiety to achieve improved resolution. For example, the resin material may include a material including a polycyclic group (e.g., the moiety).

In one or more embodiments, the resin material may include a material including a hydroxyl group, an acrylate-based material, and/or a material including a polycyclic group. For example, the material including a hydroxyl group may include a material represented by the following Chemical Formula 6-1. The acrylate-based material may include a material represented by the following Chemical Formula 6-2. The material including a polycyclic group may include a material represented by the following Chemical Formula 6-3.

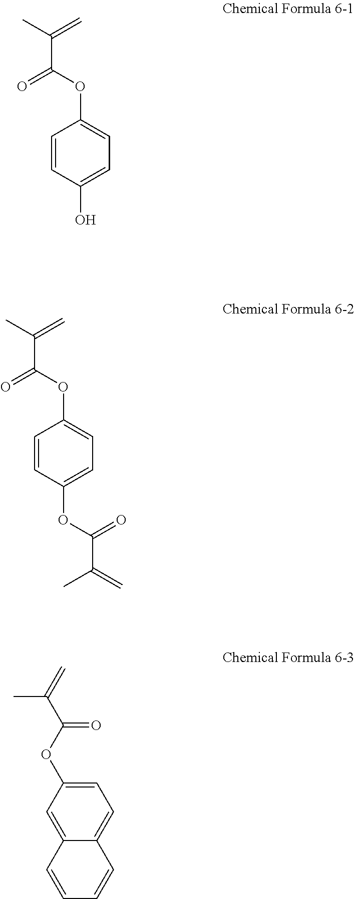

In one or more embodiments, an amount of the resin material may be about 42 wt % to about 97.65 wt % relative to 100 wt % of a total weight of the solid content of the photosensitive resin composition. For example, in some embodiments, if (e.g., when) the resin material includes a material including a hydroxyl group, an acrylate-based material, and a material including a polycyclic group, an amount of the material including the hydroxyl group may be about 40 wt % to about 70 wt % relative to 100 wt % of the total weight of the solid content of the photosensitive resin composition, an amount of the acrylate-based material may be about 1 wt % to about 20 wt % relative to 100 wt % of the total weight of the solid content of the photosensitive resin composition, and an amount of the material including the polycyclic group may be about 1 wt % to about 20 wt % relative to 100 wt % of the total weight of the solid content of the photosensitive resin composition. In some embodiments, if (e.g., when) the aforementioned numerical range (e.g., relative to 100 wt % of the total weight of the solid content of the photosensitive resin composition, the amount of the material including the hydroxyl group being about 40 wt % to about 70 wt %, the amount of the acrylate-based material being about 1 wt % to about 20 wt %, and the amount of the material including the polycyclic group about 1 wt % to about 20 wt %) is satisfied, a photosensitive resin composition having enhanced development characteristics and improved cross-linking characteristics and resolution may be provided.

### (B) Photosensitizer

The photosensitizer may include a photo active compound (PAC). The photosensitizer may make the resin material soluble or insoluble in a developer, thereby allowing exposed and unexposed portions of the photosensitive resin composition to be developed. In one or more embodiment, the photosensitizer may include a photo active generator (PAG).

The photosensitizer may include a plurality of photosensitizers. For example, the photosensitizer may include one or more selected from among a material represented by the following Chemical Formula 7-1, a material represented by the following Chemical Formula 7-2, and/or a material represented by the following Chemical Formula 7-3.

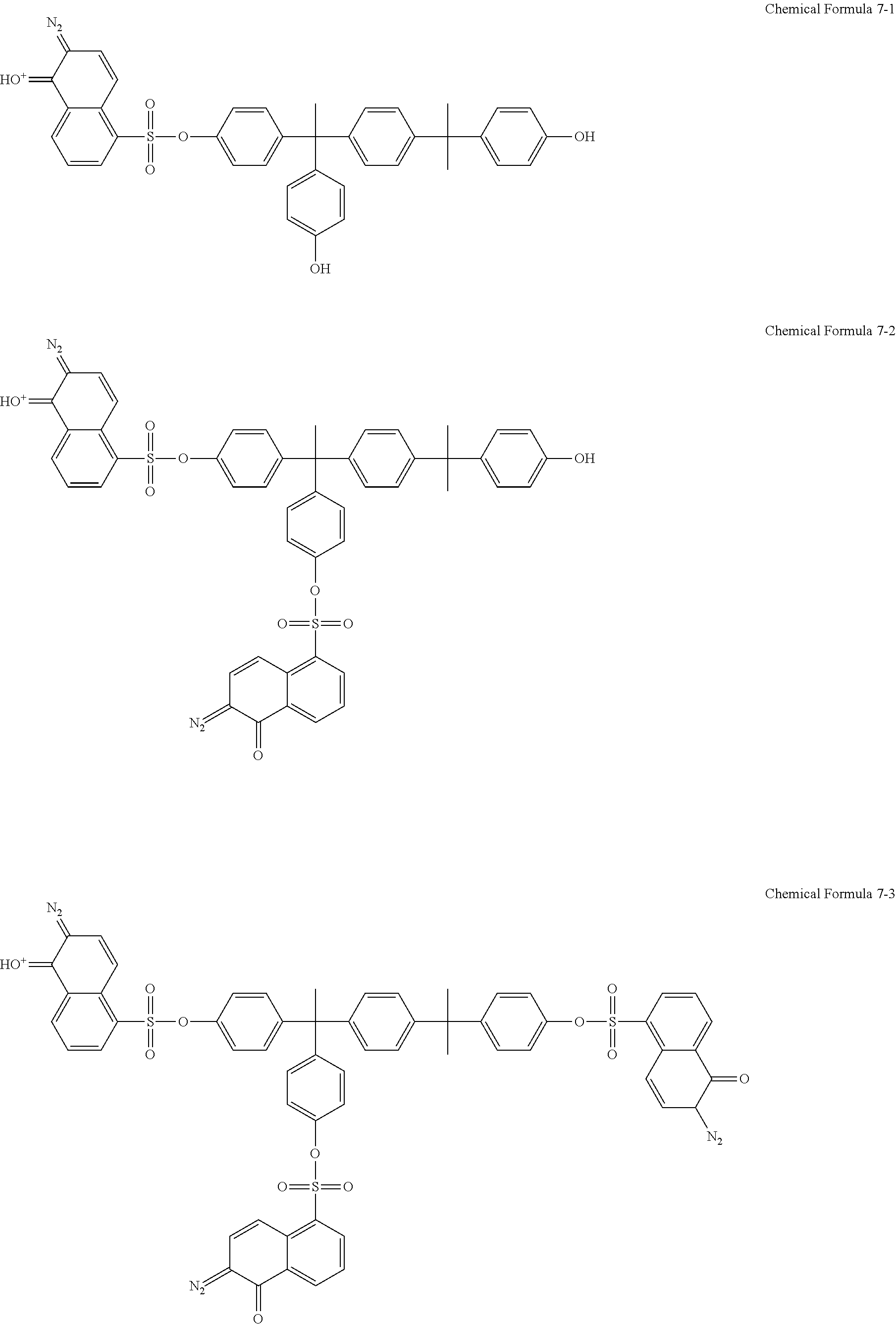

In one or more embodiments, an amount of the photosensitizer may be about 0.2 wt % to about 20 wt % relative to 100 wt % of a total weight of the solid content of the photosensitive resin composition. For example, in some embodiments, if (e.g., when) the photosensitizer includes the material represented by the following Chemical Formula 7-1, the material represented by the following Chemical Formula 7-2, and the material represented by the following Chemical Formula 7-3, an amount of the material represented by the following Chemical Formula 7-1 may be about 0.5 wt % to about 5 wt % relative to 100 wt % of a total weight of the photosensitizer, an amount of the material represented by the following Chemical Formula 7-2 may be about 1 wt % to about 10 wt % relative to 100 wt % of the total weight of the photosensitizer, and an amount of the material represented by the following Chemical Formula 7-3 may be about 89.5 wt % to about 97 wt % relative to 100 wt % of the total weight of the photosensitizer.

### (C) Plasticizer

The plasticizer may be a compound that provides plasticity. In one or more embodiments, the photosensitive resin composition may include the plasticizer, thereby improving process performance when a process (e.g., a spin coating process) for forming a layer including the photosensitive resin composition is performed.

The plasticizer may include various suitable thermoplastic materials. For example, the plasticizer may include a material represented by the following Chemical Formula 8.

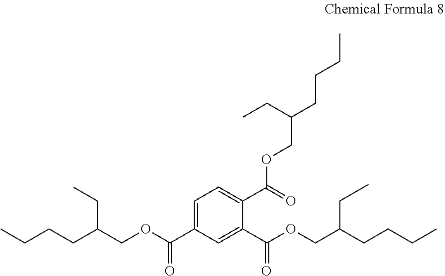 [SMILES: CCCCC(CC)COC(=O)c1ccc(C(=O)OCC(CC)CCCC)c(C(=O)OCC(CC)CCCC)c1]

In one or more embodiments, an amount of the plasticizer may be about 0.1 wt % to about 10 wt % relative to 100 wt % of a total weight of the solid content of the photosensitive resin composition.

### (D) Initiator

The initiator may be provided to initiate polymerization of the photosensitive resin composition. The initiator may include a plurality of initiators.

In an embodiment, the initiator may include materials including a carboxyl group or an ester group. For example, the initiator may include one or more selected from among a material represented by the following Chemical Formula 9-1, a material represented by the following Chemical Formula 9-2, a material represented by the following Chemical Formula 9-3, a material represented by the following Chemical Formula 9-4, a material represented by the following Chemical Formula 9-5, a material represented by the following Chemical Formula 9-6, and/or a material represented by the following Chemical Formula 9-7. For example, the initiator may include all of the materials according to Chemical Formulas 9-1 to 9-7.

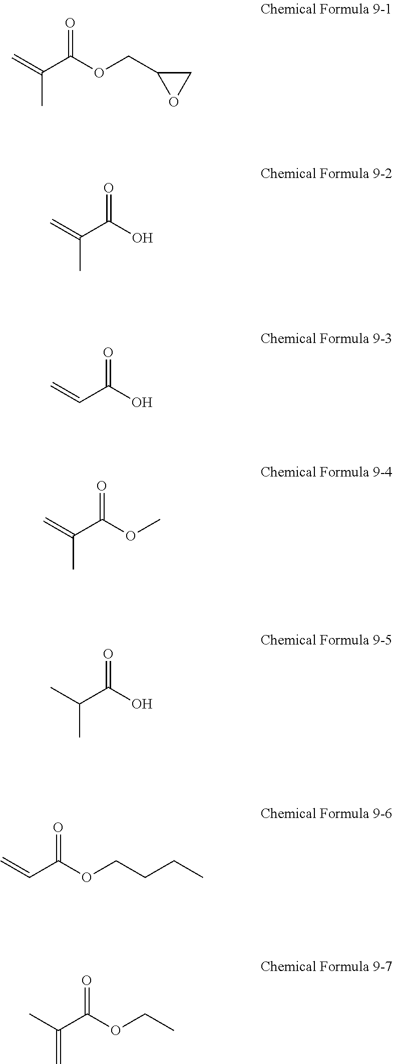

In one or more embodiments, an amount of the initiator may be about 2 wt % to about 57.65 wt % (e.g., about 2 wt % to about 20 wt %) relative to 100 wt % of a total weight of the solid content of the photosensitive resin composition. For example, the initiator may include one or more selected from among the material represented by the following Chemical Formula 9-1, the material represented by the following Chemical Formula 9-2, the material represented by the following Chemical Formula 9-3, the material represented by the following Chemical Formula 9-4, the material represented by the following Chemical Formula 9-5, the material represented by the following Chemical Formula 9-6, and/or the material represented by the following Chemical Formula 9-7. In some embodiments, if (e.g., when) the material according to Chemical Formula 9-1 is included, an amount of the material according to Chemical Formula 9-1 may be about 1 wt % to about 15 wt % relative to 100 wt % of the total weight of the solid content of the photosensitive resin composition. In some embodiments, if (e.g., when) the material according to Chemical Formula 9-2 is included, an amount of the material according to Chemical Formula 9-2 may be about 1 wt % to about 10 wt % relative to 100 wt % of the total weight of the solid content of the photosensitive resin composition. In some embodiments, if (e.g., when) the material according to Chemical Formula 9-3 is included, an amount of the material according to Chemical Formula 9-3 may be about 0.1 wt % to about 10 wt % relative to 100 wt % of the total weight of the solid content of the photosensitive resin composition. In some embodiments, if (e.g., when) the material according to Chemical Formula 9-4 is included, an amount of the material according to Chemical Formula 9-4 may be about 1 wt % to about 10 wt % relative to 100 wt % of the total weight of the solid content of the photosensitive resin composition. In some embodiments, if (e.g., when) the material according to Chemical Formula 9-5 is included, an amount of the material according to Chemical Formula 9-5 may be about 0.1 wt % to about 10 wt % relative to 100 wt % of the total weight of the solid content of the photosensitive resin composition. In some embodiments, if (e.g., when) the material according to Chemical Formula 9-6 is included, an amount of the material according to Chemical Formula 9-6 may be about 15 wt % to about 35 wt % relative to 100 wt % of the total weight of the solid content of the photosensitive resin composition. In some embodiments, if (e.g., when) the material according to Chemical Formula 9-7 is included, an amount of the material according to Chemical Formula 9-7 may be about 0.1 wt % to about 5 wt % relative to 100 wt % of the total weight of the solid content of the photosensitive resin composition. For example, in some embodiments, if (e.g., when) the initiator includes the material according to Chemical Formula 9-1 and the material according to Chemical Formula 9-2, an amount of the material according to Chemical Formula 9-1 may be about 1 wt % to about 15 wt % relative to 100 wt % of the total weight of the solid content of the photosensitive resin composition, and an amount of the material according to Chemical Formula 9-2 may be about 1 wt % to about 10 wt % relative to 100 wt % of the total weight of the solid content of the photosensitive resin composition.

### (E) Surfactant

The surfactant may enhance coating properties of the photosensitive resin composition and improve viscosity properties of the photosensitive resin composition. The surfactant may include various suitable surfactant(s).

In an embodiment, the surfactant may include one or more selected from among a fluoro-based surfactant and a silicon-based surfactant. In some embodiments, the surfactant may enhance the coating properties, such as the spreadability of the photosensitive resin composition. Hence, the processability of the process involving the photosensitive resin composition may be enhanced.

In one or more embodiments, an amount of the surfactant may be about 0.05 wt % to about 3 wt % relative to 100 wt % of a total weight of the solid content of the photosensitive resin composition. As the aforementioned numerical range (e.g., the amount of the surfactant being about 0.05 wt % to about 3 wt % relative to 100 wt % of a total weight of the solid content of the photosensitive resin composition) is satisfied, the photosensitive resin composition may satisfy a set or certain viscosity numerical range in relation to the content of the solvent with respect to the photosensitive resin composition.

### (F) Solvent

The solvent may include various suitable organic solvents, which may provide (e.g., taking into account) the dispersibility of the photosensitive resin composition and the solubility of the materials forming the photosensitive resin composition.

In one or more embodiments, the solvent may include an organic solvent. For example, the solvent may include propylene glycol monomethyl ether (PGME).

In one or more embodiments, an amount of the solvent may be about 60 wt % to about 90 wt % relative to 100 wt % of a total weight of the photosensitive resin composition. In some embodiments, if (e.g., when) the aforementioned numerical range (e.g., the amount of the solvent being about 60 wt % to about 90 wt % relative to 100 wt % of the total weight of the photosensitive resin composition) is satisfied, the photosensitive resin composition may have a viscosity in a range from about 5 cP to about 20 cP.

In one or more embodiments, the solvent may be included in an amount corresponding to the aforementioned numerical range with respect to the photosensitive resin composition (e.g., the amount of the solvent being about 60 wt % to about 90 wt % relative to 100 wt % of the total weight of the photosensitive resin composition), thus enabling the viscosity of the photosensitive resin composition to decrease to have the foregoing viscosity range (e.g., the viscosity ranging from about 5 cP to about 20 cP). Accordingly, if (e.g., when) a layer based on the photosensitive resin composition is formed through a spin coating process, the formed layer may have a relatively large thickness.

### (G) Others

In one or more embodiments, the photosensitive resin composition may further include additional additives in addition to the aforementioned materials (e.g., resin material, photosensitizer, plasticizer, initiator, surfactant, and a solvent). For example, the photosensitive resin composition may further include various suitable additives, such as a sensitizer, a dispersant, an antioxidant, an thermal polymerization inhibitor, and/or a leveling agent. However, the present disclosure is not limited to a specific example.

### 4. Method of Manufacturing Display Device

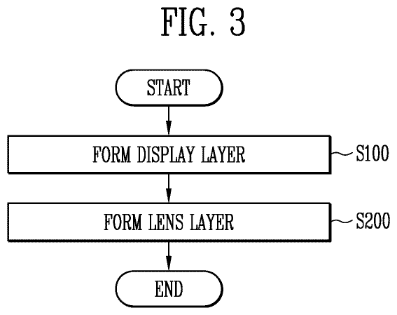

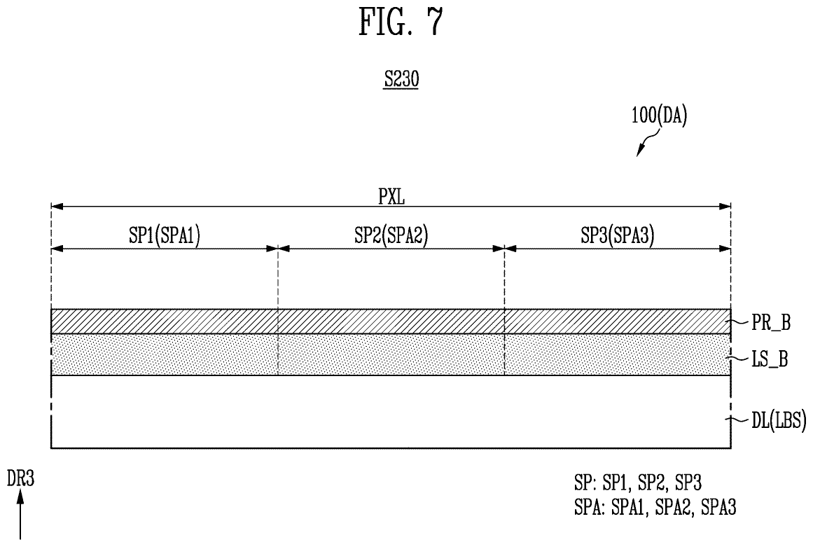

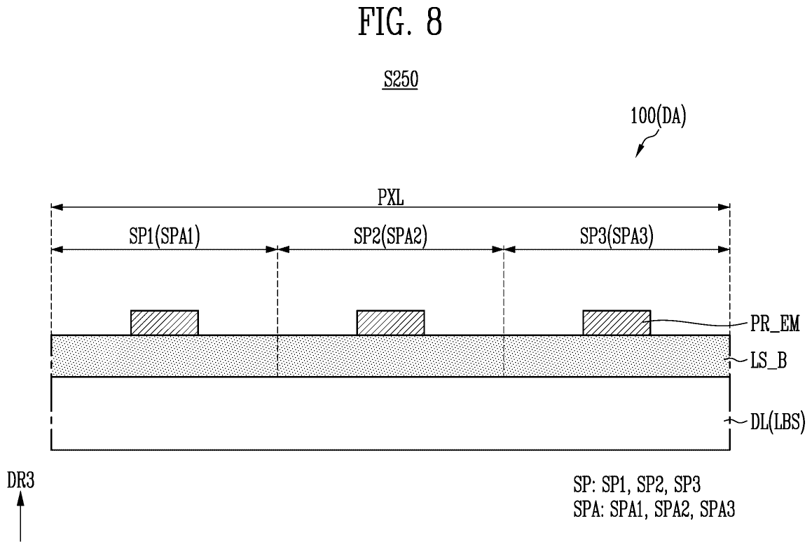

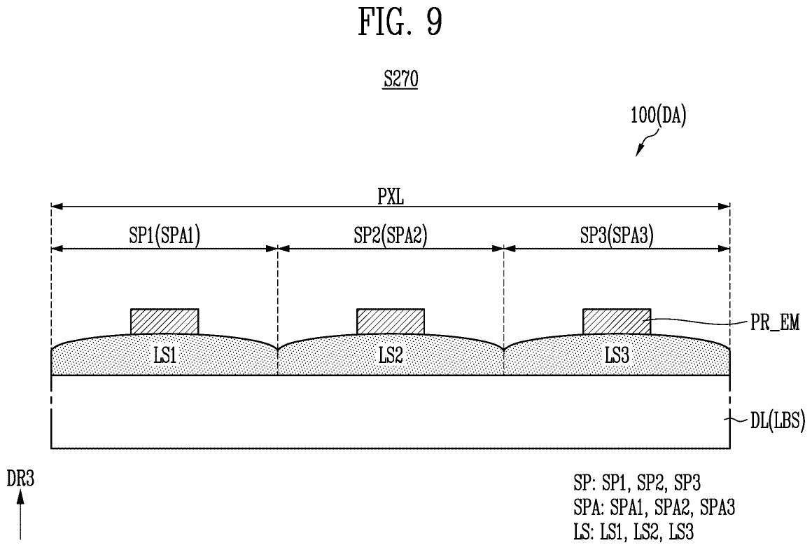

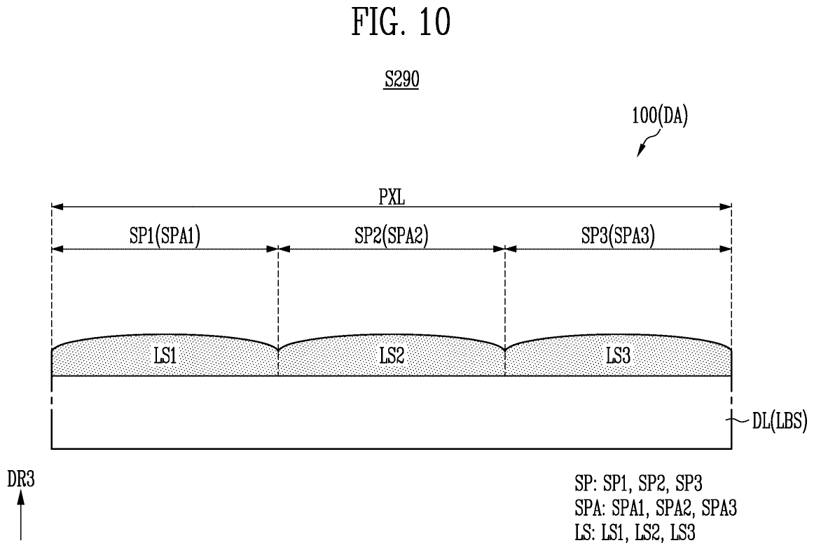

Hereinafter, in one or more embodiments, a method for manufacturing the display device 100 will be described with reference to FIGS. 3 to 16.

In one or more embodiments, FIGS. 3 to 16 are diagrams illustrating a method for manufacturing the display device 100.

In one or more embodiments, FIG. 3 is a flowchart illustrating a method for manufacturing the display device 100.

In one or more embodiments, referring to FIG. 3, the method for manufacturing the display device 100 may include step (e.g., act or task) S100 of forming a display layer, and step (e.g., act or task) S200 of forming a lens layer.

First, a method for manufacturing the display device 100 in accordance with one or more embodiments will be described with reference to FIGS. 3 to 10.

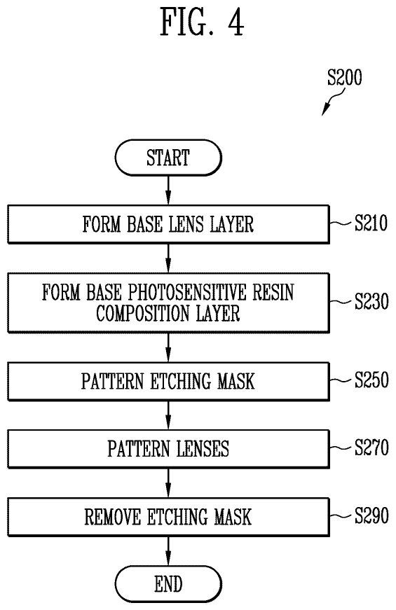

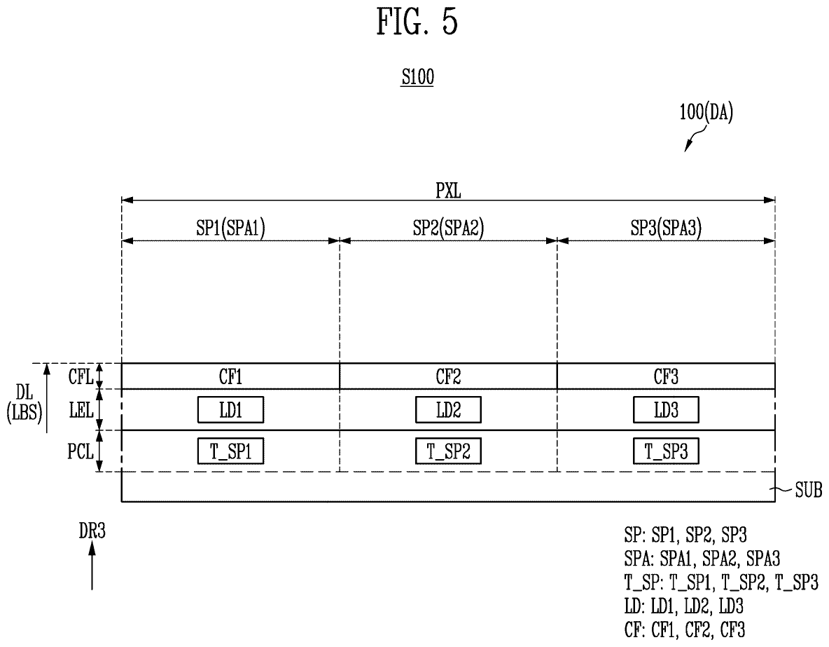

In one or more embodiments, FIG. 4 is a flowchart illustrating the step (e.g., act or task) of forming a lens layer. In one or more embodiments, FIGS. 5-10 are each schematic views illustrating, by process steps (e.g., acts or tasks), the method for manufacturing the display device 100. For convenience of description, FIGS. 5-10 each schematically illustrate a cross-sectional structure described above with reference to FIG. 2.

Referring to FIG. 4, step (e.g., act or task) S200 of forming the lens layer may include step (e.g., act or task) S210 of forming a base lens layer, step (e.g., act or task) S230 of forming a base photosensitive resin composition layer, step (e.g., act or task) S250 of patterning an etching mask, step (e.g., act or task) S270 of patterning lenses, and step (e.g., act or task) S290 of removing the etching mask.

Referring to FIGS. 3 and 5, in step (e.g., act or task) S100 of forming the display layer, the lens base layer LBS may be formed.

In the present step (e.g., act or task) S100, the pixel circuit layer PCL may be formed by patterning a circuit element (e.g., transistors T_SP) on the substrate SUB. The light-emitting-element layer LEL may be formed by providing light emitting elements LD on the pixel circuit layer PCL. The color filter layer CFL may be formed by patterning the color filters CF on the light-emitting-element layer LEL.

In one or more embodiments, a conductive layer (e.g., an electrically conductive layer) or insulating layer (e.g., an electrically insulating layer) on the substrate SUB may be formed based on a process for manufacturing a semiconductor device. For example, the conductive layer or the insulating layer on the substrate SUB may be formed through a photolithography process, may be etched by various suitable methods (e.g., wet etching, dry etching, and/or the like), and may be deposited by various suitable methods (e.g., sputtering, chemical vapor deposition (CVD), atomic layer deposition (ALD), and/or the like). In one or more embodiments, various deposition processes may be performed to form the light emitting elements LD. However, the present disclosure is not limited to a specific embodiment.

In the present step (e.g., act or task) S100, the first transistor T_SP1, the first light emitting element LD1, and the first color filter CF1 may be in the first sub-pixel area SPA1, and the first sub-pixel SP1 may be formed. The second transistor T_SP2, the second light emitting element LD2, and the second color filter CF2 may be in the second sub-pixel area SPA2, and the second sub-pixel SP2 may be formed. The third transistor T_SP3, the third light emitting element LD3, and the third color filter CF3 may be in the third sub-pixel area SPA3, and the third sub-pixel SP3 may be formed.

Referring to FIGS. 3, 4, and 6, in step (e.g., act or task) S200 of forming the lens layer, step (e.g., act or task) S210 of forming the base lens layer may be performed.

In the present step (e.g., act or task) S210, the base lens layer LS_B including the resin composition for lenses described above may be formed on the lens base layer LBS (e.g., the display layer DL). The base lens layer LS_B may be formed, and a curing process for the base lens layer LS_B may be further performed. Accordingly, the cured base lens layer LS_B may be manufactured.

In the present step (e.g., act or task) S210, the environment in which the curing process is performed is not particularly limited. For example, to perform the curing process, light (e.g., light having a wavelength of approximately 365 nm as ultraviolet (UV) light) may be applied to the base lens layer LS_B, and thermal energy may be applied to the base lens layer LS_B.

In one or more embodiments, the base lens layer LS_B may include a resin composition for lenses. The resin composition for lenses may include an auxiliary initiator and/or a thermal initiator, whereby the degree of cross-liking of the resin composition for lenses may be excellent during the curing process.

In the present step (e.g., act or task) S210, the base lens layer LS_B may be over the first to third sub-pixel areas SPA1 to SPA3, and may have a generally uniform thickness.

Referring to FIGS. 3, 4, and 7, in step (e.g., act or task) S200 of forming the lens layer, step (e.g., act or task) S230 of forming a base photosensitive resin composition layer may be performed.

In the present step (e.g., act or task) S230, a base photosensitive resin composition layer PR_B including the photosensitive resin composition described above may be formed on the cured base lens layer LS_B. The base photosensitive resin composition layer PR_B may be formed, and a curing process for the base photosensitive resin composition layer PR_B may be further performed. Accordingly, the cured base photosensitive resin composition layer PR_B may be manufactured.

In the present step (e.g., act or task) S230, the base photosensitive resin composition layer PR_B may be formed through a spin coating process. However, the present disclosure is not limited to the aforementioned embodiment.

In the present step (e.g., act or task) S230, the environment in which the curing process is performed is not particularly limited. For example, to perform the curing process, light may be applied to the base photosensitive resin composition layer PR_B, and thermal energy may be applied to the base photosensitive resin composition layer PR_B.

In one or more embodiments, the base photosensitive resin composition layer PR_B may include a photosensitive resin composition. The photosensitive resin composition may include an acrylate-based material, whereby the degree of cross-liking of the photosensitive resin composition may be excellent during the curing process.

In one or more embodiments, the base lens layer LS_B may include a resin composition for lenses. The resin composition for lenses may include a resin material including a carbazole-based material, whereby the base lens layer LS_B may have excellent chemical resistance. Accordingly, at an interface between the base lens layer LS_B and the base photosensitive resin composition layer PR_B, the risk of respective layers being mixed may be reduced.

In the present step (e.g., act or task) S230, the base photosensitive resin composition layer PR_B may be over the first to third sub-pixel areas SPA1 to SPA3, and may have a generally uniform thickness.

Referring to FIGS. 3, 4, and 8, in step (e.g., act or task) S200 of forming the lens layer, step (e.g., act or task) S250 of patterning an etching mask may be performed.

In the present step (e.g., act or task) S250, the base photosensitive resin composition layer PR_B may be patterned, and the etching mask PR_EM may be manufactured (e.g., formed).

In the present step (e.g., act or task) S250, an exposure process for the base photosensitive resin composition layer PR_B may be performed, whereby at least a portion of the base photosensitive resin composition layer PR_B may be removed.

In one or more embodiments, the base photosensitive resin composition layer PR_B may include a resin material including a material including hydroxyl group, an acrylate-based material, and/or a material including a polycyclic group. Hence, development characteristics and resolution in the exposure process may be excellent. Accordingly, the base photosensitive resin composition layer PR_B may be appropriately patterned to enable an intended structure to be manufactured. For example, the etching mask PR_EM may be patterned to have an intended profile.

In one or more embodiments, etching masks PR_EM manufactured at the present step (e.g., act or task) S250 may be separated from each other in the first to third sub-pixel areas SPA1 to SPA3.

Referring to FIGS. 3, 4, and 9, in step (e.g., act or task) S200 of forming the lens layer, step (e.g., act or task) S270 of patterning lenses may be performed.

In the present step (e.g., act or task) S270, at least a portion of the base lens layer LS_B may be removed utilizing the etching mask PR_EM, so that lenses LS may be patterned.

In the present step (e.g., act or task) S270, first to third lenses LS1 to LS3 may be formed. Furthermore, in one or more embodiments, the lenses LS may be manufactured based on the resin composition for lenses, thus having excellent high refractive characteristics.

Referring to FIGS. 3, 4, and 10, in step (e.g., act or task) S200 of forming the lens layer, step (e.g., act or task) S290 of removing the etching mask may be performed.

In the present step (e.g., act or task) S290, the etching mask PR_EM may be removed, and upper surfaces of the lenses LS may be exposed. In one or more embodiments, an ashing process may be performed, but the present disclosure is not limited thereto.

Thereafter, in one or more embodiments, an overcoat layer OC and a cover window CW may be further formed, and the display device 100 may be provided.

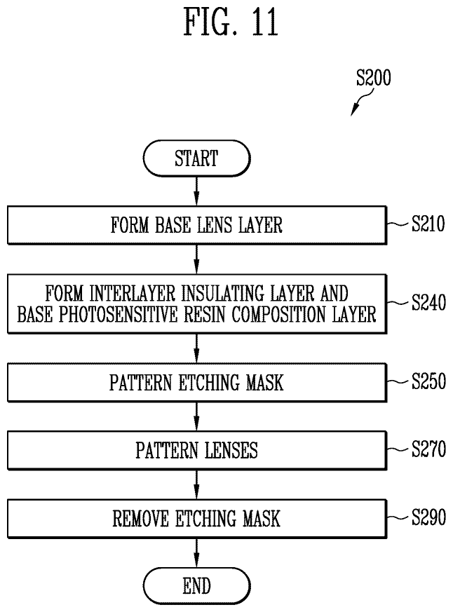

Next, in one or more embodiments, a method for manufacturing the display device 100 will be described with reference to FIGS. 11-14. Description overlapping that of the embodiments described above will be simplified, or may not be repeated.

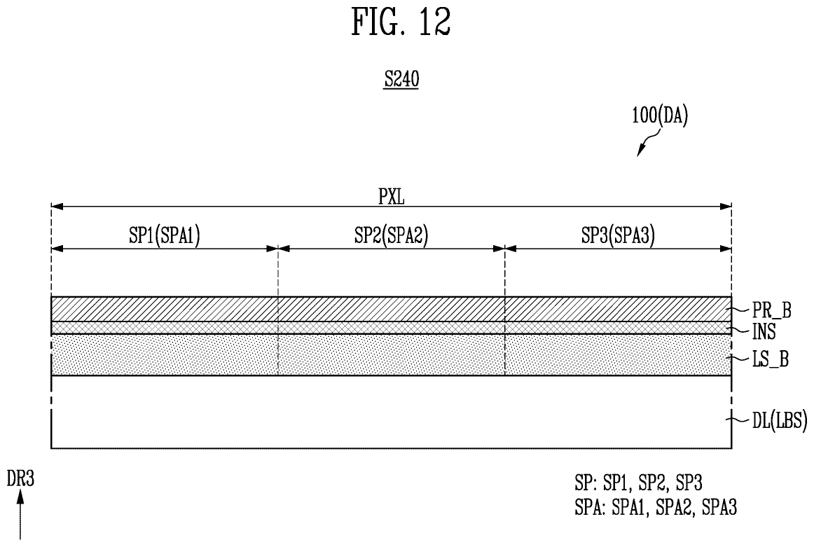

FIG. 11 is a flowchart illustrating the step (e.g., act or task) of forming a lens layer in accordance with one or more embodiments. FIGS. 12 to 14 are schematic sectional views illustrating, by process steps (e.g., acts or tasks), the method for manufacturing the display device 100 in accordance with one or more embodiment. For convenience of description, FIGS. 12-14 schematically illustrate the cross-sectional structure described with reference to FIG. 2.

Referring to FIG. 11, step (e.g., act or task) S200 of forming the lens layer may include step (e.g., act or task) S210 of forming a base lens layer, step (e.g., act or task) S240 of forming an interlayer insulating layer and a base photosensitive resin composition layer, step (e.g., act or task) S250 of patterning an etching mask, step (e.g., act or task) S270 of patterning lenses, and step (e.g., act or task) S290 of removing the etching mask.

In some embodiments, the method for manufacturing the display device 100 may include step (e.g., act or task) S240 of forming the interlayer insulating layer and the base photosensitive resin composition layer.

Referring to FIGS. 11 and 12, in step (e.g., act or task) S240 of forming the interlayer insulating layer and the base photosensitive resin composition layer, the interlayer insulating layer INS may be formed on the base lens layer LS_B, and the base photosensitive resin composition layer PR_B may be formed on the interlayer insulating layer INS. Accordingly, the base lens layer LS_B and the base photosensitive resin composition layer PR_B may be physically spaced apart from (e.g., separated from) each other by the interlayer insulating layer INS. Accordingly, the risk of the base lens layer LS_B and the base photosensitive resin composition layer PR_B being mixed with each other may be reduced.

In the present step (e.g., act or task) S240, the interlayer insulating layer INS may be formed by chemical vapor deposition, atomic layer deposition, and/or the like. In one or more embodiments, the interlayer insulating layer INS may include inorganic material. For example, the interlayer insulating layer INS may include one or more selected from among silicon oxide (SiOx), silicon nitride (SiNx), and/or silicon oxynitride (SiOxNy). However, the present disclosure is not limited to the aforementioned embodiment.

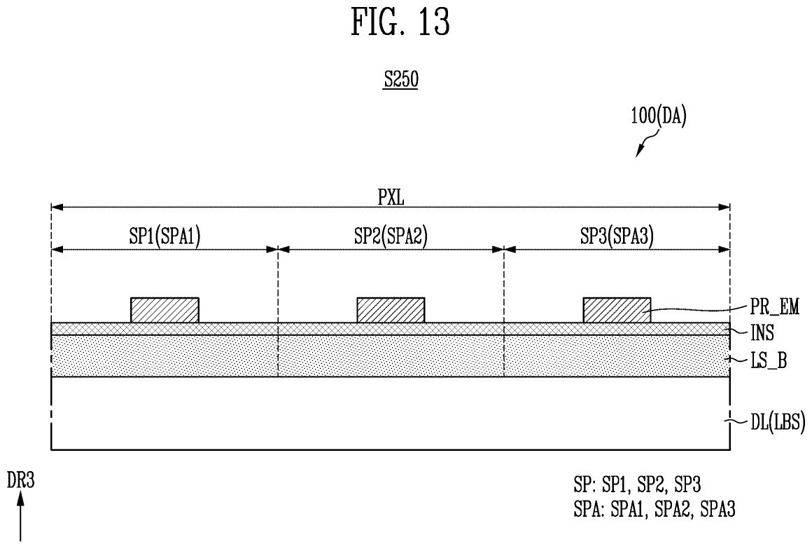

Referring to FIGS. 11 and 13, in step (e.g., act or task) S250 of patterning the etching mask, the etching mask PR_EM may be patterned by removing at least a portion of the base photosensitive resin composition layer PR_B, and the interlayer insulating layer INS may be exposed.

In the present step (e.g., act or task) S250, the interlayer insulating layer INS may cover an upper surface of the base lens layer LS_B, such that the upper surface of the base lens layer LS_B may not be exposed.

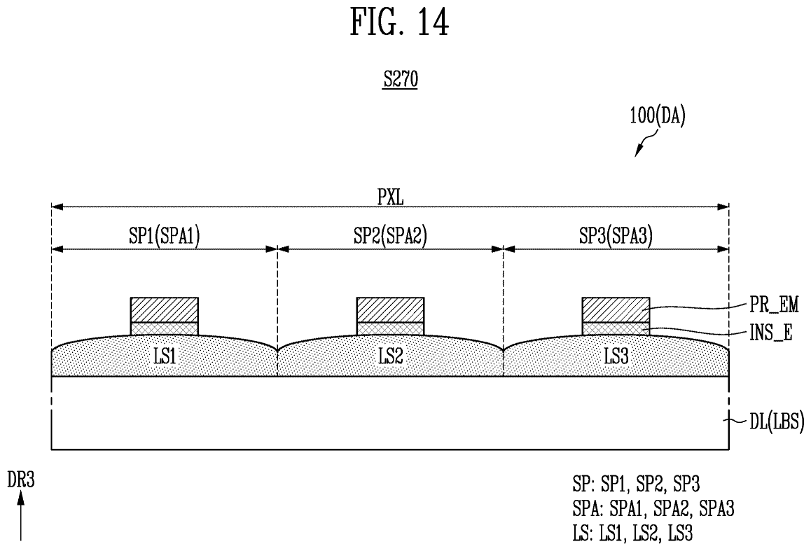

Referring to FIGS. 11 and 14, in step (e.g., act or task) S270 of patterning the lenses, the lenses LS may be patterned, and at least a portion of the interlayer insulating layer INS may be removed, thereby patterning an etched interlayer insulating layer INS_E.

In the present step (e.g., act or task) S270, the etched interlayer insulating layer INS_E may cover upper surfaces of the first to third lenses LS1 to LS3, such that at least portions of the upper surfaces of the first to third lenses LS1 to LS3 may be exposed.

Referring to FIG. 11, in step (e.g., act or task) S290 of removing the etching mask, the etching mask PR_EM and the etched interlayer insulating layer INS_E may be removed. In one or more embodiments, in the present step (e.g., act or task) S290, an ashing process and/or the like may be performed.

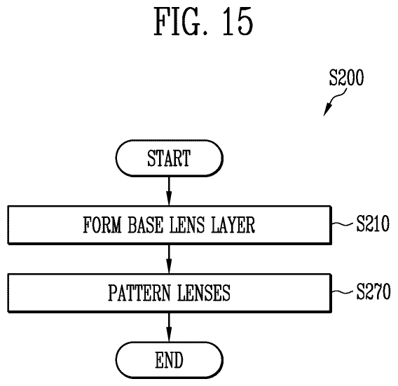

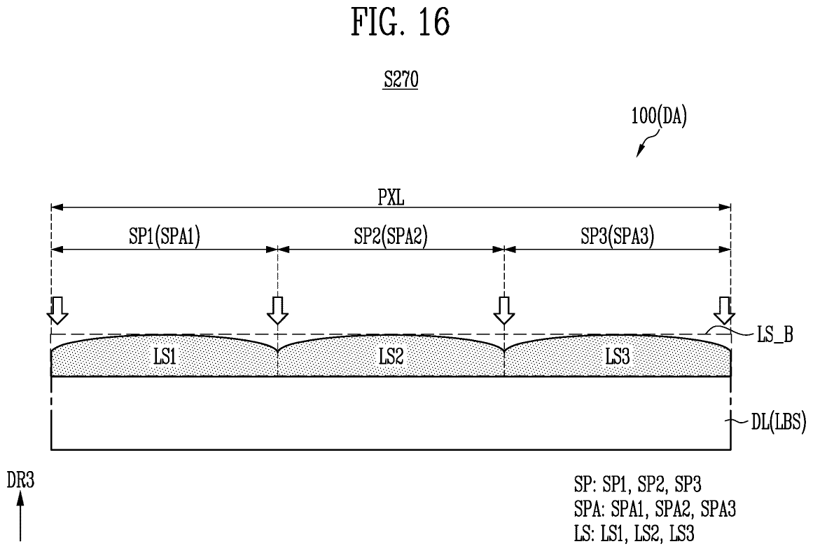

Next, a method for manufacturing the display device 100 in accordance with one or more embodiments will be described with reference to FIGS. 15 and 16. Description overlapping that of the embodiments described above will be simplified, or may not be repeated.

FIG. 15 is a flowchart illustrating the step (e.g., act or task) of forming a lens layer in accordance with the present embodiment. FIG. 16 is a schematic sectional view illustrating, by process steps (e.g., acts or tasks), the method for manufacturing the display device 100 in accordance with one or more embodiments. For convenience of description, FIG. 16 schematically illustrates the cross-sectional structure described with reference to FIG. 2.

Referring to FIG. 15, step (e.g., act or task) S200 of forming the lens layer in accordance with one or more embodiments may include step (e.g., act or task) S210 of forming a base lens layer, and step (e.g., act or task) S270 of patterning lenses.

In the method for manufacturing the display device 100 in accordance with one or more embodiments, the etching process may be directly performed on the base lens layer LS_B without an etching mask utilizing a photosensitive resin composition, thereby patterning lenses LS. For example, referring to FIGS. 15 and 16, before step (e.g., act or task) S270 of patterning the lenses is performed, the lenses LS may be manufactured by etching the base lens layer LS_B without forming a layer based on a photosensitive resin composition on the base lens layer LS_B. Accordingly, the process steps (e.g., acts or tasks) may be simplified, and the process costs may be reduced.

### 5. Application Example

In one or more embodiments, The display device 100 may be applied to various suitable fields and/or products.

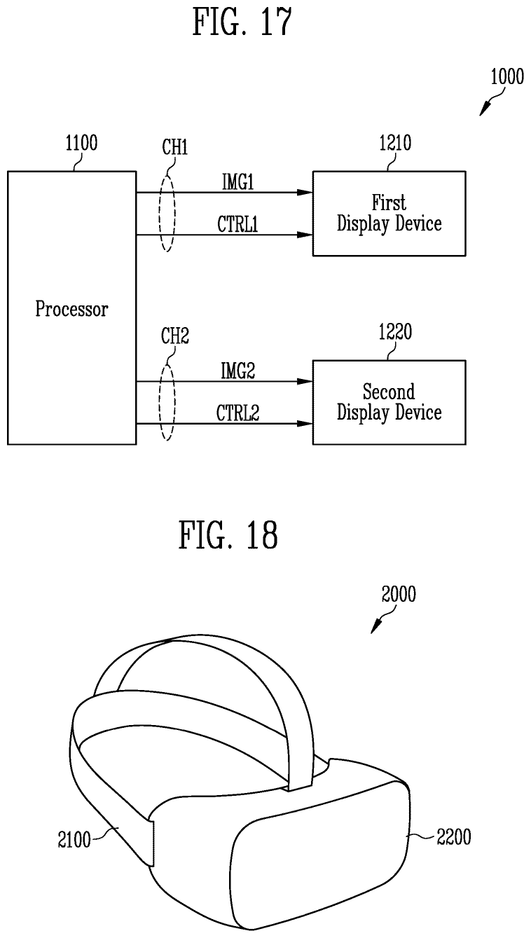

Hereinafter, an electronic device 1000 to which the display device 100 is applied and an application example to which the electronic device 1000 is applied will be described with reference to FIGS. 17-19.

FIG. 17 is a block diagram illustrating an embodiment of the electronic device 1000.

Referring to FIG. 17, the electronic device 1000 may include a processor 1100, and one or more display devices 1210 and 1220. The electronic device 1000 may implement a display system.

The processor 1100 may perform various suitable tasks and operations. In one or more embodiments, the processor 1100 may include an application processor, a graphic processor, a microprocessor, a central processing unit (CPU), and/or the like. The processor 1100 may be connected to the other components of the electronic device 1000 through a bus system to control the components.

According to an embodiment, the processor 1100 may provide input image data to the display device 1210, 1220, and the display device 1210, 1220 may display images based on the input image data provided by the processor 1100.

In FIG. 17, in one or more embodiments, the electronic device 1000 may include the first and second display devices 1210 and 1220. The processor 1100 may be connected to the first display device 1210 through a first channel CH1, and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured in the same manner as the display device 100 described with reference to FIG. 1.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured in the same manner as the display device 100 described with reference to FIG. 1.

The electronic device 1000 may include computing systems that provide an image display function, such as a portable computer, a mobile phone, a smart phone, a tablet personal computer (tablet PC), a smart watch, a watch phone, a portable multimedia player, a navigation system, and/or an ultra mobile personal computer (UMPC). Furthermore, the electronic device 1000 may include at least one of a head mounted display (HMD), a virtual reality (VR) device, a mixed reality (MR) device, and/or an augmented reality (AR) device.

According to an embodiment, the electronic device 1000 may further include a memory device, a storage device, an input/output (I/O) device, a power supply.

The memory device may store data needed to perform the operation of the electronic device. For example, the memory device may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

FIG. 18 is a perspective diagram illustrating an application example of the electronic device 1000 of FIG. 17.

Referring to FIG. 18, the electronic device 1000 of FIG. 17 may be applied to a head-mounted display device 2000. The head-mounted display device 2000 may be a wearable electronic device, which may be worn on the head of the user.

The head-mounted display 2000 may include a head-mounted band 2100 and a display device reception casing 2200. The head-mounted band 2100 may be connected to the display device reception casing 2200. The head-mounted band 2100 may include a horizontal band and/or a vertical band to fasten the head-mounted display 2000 to the head of the user. The horizontal band may enclose the sides of the head of the user, and the vertical band may enclose the top of the head of the user. However, the embodiments are not limited to the aforementioned embodiment. For example, the head-mounted band 2100 may be implemented in the form of eyeglass frames, a helmet, and/or the like.

The display device reception casing 2200 may receive the first and second display devices 1210 and 1220 of FIG. 17. The display device reception casing 2200 may further receive the processor 1100 of FIG. 17.

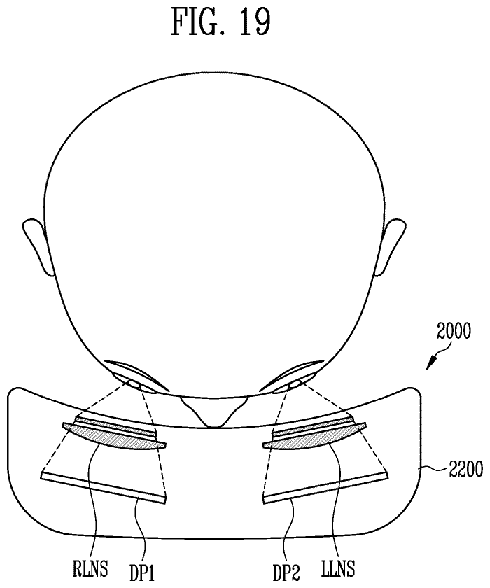

FIG. 19 is a diagram illustrating the head-mounted display device 2000 of FIG. 18 that is worn on a user.

Referring to FIG. 19, the first display panel DP1 of the first display device 1210 and the second display panel DP2 of the second display device 1220 are in the head mounted display 2000. The head-mounted display 2000 may further include one or more lenses LLNS and RLNS.

In the display device reception casing 2200, the right-eye lens RLNS may be between the first display panel DP1 and the right eye of the user. In the display device reception casing 2200, the left-eye lens LLNS may be between the second display panel DP2 and the left eye of the user.

An image outputted from the first display panel DP1 may be viewed by the right eye of the user through the right-eye lens RLNS. The right-eye lens RLNS may refract light emitted from the first display panel DP1 toward the right eye of the user. The right-eye lens RLNS may perform an optical function to adjust a viewing distance between the first display panel DP1 and the right eye of the user.

An image outputted from the second display panel DP2 may be viewed by the left eye of the user through the left-eye lens LLNS. The left-eye lens LLNS may refract light emitted from the second display panel DP2 toward the left eye of the user. The left-eye lens LLNS may perform an optical function to adjust a viewing distance between the second display panel DP2 and the left eye of the user.

In one or more embodiments, each of the right-eye lens RLNS and the left-eye lens LLNS may include an optical lens having a pancake-shaped cross-section (e.g., a cross section that shows a shape of a pancake, refer to FIG. 19). In one or more embodiments, each of the right-eye lens RLNS and the left-eye lens LLNS may include a multi-channel lens including sub-areas having different optical characteristics. In some embodiments, each display panel may output images respectively corresponding to sub-areas of the multi-channel lens. The output images may be viewed by the user through the corresponding sub-areas.

One or more embodiments of the present disclosure may provide a resin composition for lenses, a photosensitive resin composition, a method for manufacturing a display device including a lens, a display device including a lens, and an electronic device comprising the display device, in which a lens structure may have excellent high refractive characteristics, so that light output efficiency of the display device may be enhanced.

One or more embodiments of the present disclosure may provide a resin composition for lenses, a photosensitive resin composition, a method for manufacturing a display device including a lens, a display device including a lens, and an electronic device comprising the display device, in which the lens structure having a suitable or desired thickness may be suitably or appropriately formed.

One or more embodiments of the present disclosure may provide a resin composition for lenses, a photosensitive resin composition, a method for manufacturing a display device including a lens, a display device including a lens, and an electronic device comprising the display device, in which process risk may be reduced during a process of manufacturing the lens structure, and process performance may be enhanced.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A device of preparing a resin composition, a device of preparing a photosensitive resin composition, a device of preparing a display, a battery management system (BMS) device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device utilizing a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

While various embodiments have been described above, a person of ordinary skill in the art would appreciate that various modifications, additions and substitutions are possible, without departing from the scope and spirit of the present disclosure.

Therefore, the embodiments disclosed in this specification are only for illustrative purposes rather than limiting the technical spirit of the present disclosure. The scope of the present disclosure must be defined by the accompanying claims, and equivalents thereof.

What is claimed is:

1. A resin composition for lenses, comprising:
solid content; and
an organic solvent,
wherein the solid content comprises: a resin material comprising a carbazole-based material and an acrylate-based material; a multifunctional cross-linker; an initiator comprising a thermal initiator and a photoinitiator; and a sensitizer.

2. The resin composition according to claim 1,
wherein an amount of the carbazole-based material is about 75 wt % to about 95 wt % relative to 100 wt % of a total weight of the solid content, and
wherein an amount of the acrylate-based material is about 1 wt % to about 15 wt % relative to 100 wt % of the total weight of the solid content.

3. The resin composition according to claim 2,
wherein the carbazole-based material comprises poly(9-vinylcarbazole) represented by Chemical Formula 1-1, and
wherein the acrylate-based material comprises benzyl methacrylate represented by Chemical Formula 1-2:

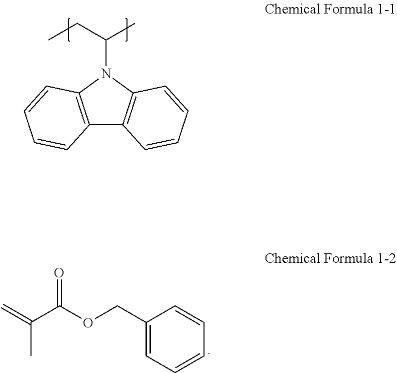

4. The resin composition according to claim 1, wherein the resin material has a refractive index in a range from about 1.55 to about 1.75 with respect to light having a wavelength of 400 nm.

5. The resin composition according to claim 1,
wherein an amount of the multifunctional cross-linker is about 1 wt % to about 15 wt % relative to 100 wt % of a total weight of the solid content, and
wherein the multifunctional cross-linker comprises a material represented by Chemical Formula 2-1 and a material represented by Chemical Formula 2-2:

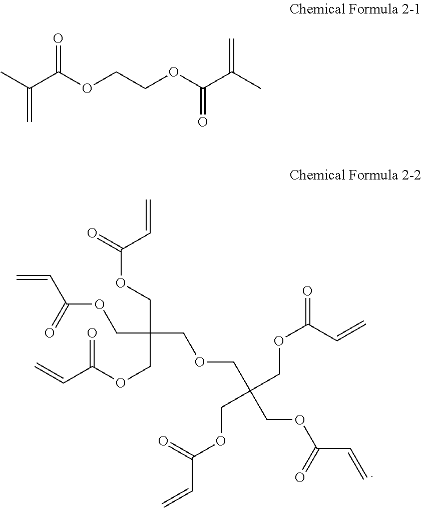

6. The resin composition according to claim 1,
wherein an amount of the thermal initiator is about 0.5 wt % to about 5 wt % relative to 100 wt % of a total weight of the solid content,
wherein an amount of the photoinitiator is about 0.1 wt % to about 10 wt % relative to 100 wt % of a total weight of the solid content,
wherein the thermal initiator comprises a material represented by Chemical Formula 3-1, and
wherein the photoinitiator comprises at least one of a material represented by Chemical Formula 3-2 or a material represented by Chemical Formula 3-3:

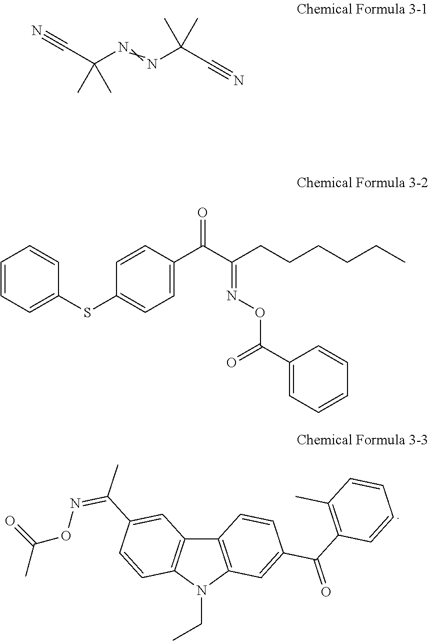 [SMILES: CC(C)(C#N)N=NC(C)(C)C#N ; CCCCCC/C(=N\OC(=O)c1ccccc1)C(=O)c1ccc(Sc2ccccc2)cc1 ; CCn1c2ccc(/C(C)=N\OC(C)=O)cc2c2ccc(C(=O)c3ccccc3C)cc21]

7. The resin composition according to claim 1, further comprising an auxiliary initiator comprising a hydroxyl group,
wherein the auxiliary initiator comprises one or more selected from among a material represented by Chemical Formula 4-1, a material represented by Chemical Formula 4-2, a material represented by Chemical Formula 4-3, a material represented by Chemical Formula 4-4, and a material represented by Chemical Formula 4-5:

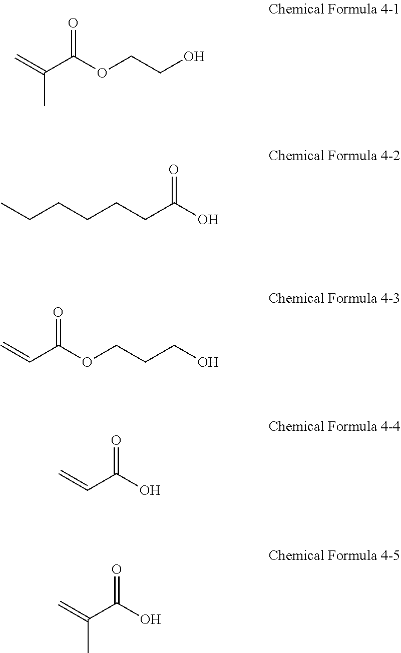

8. The resin composition according to claim 1, further comprising a sensitizer represented by Chemical Formula 5-1 or Chemical Formula 5-2, and an amount of the sensitizer represented by Chemical Formula 5-1 or Chemical Formula 5-2 is about 0.1 wt % to about 5 wt % relative to 100 wt % of a total weight of the solid content:

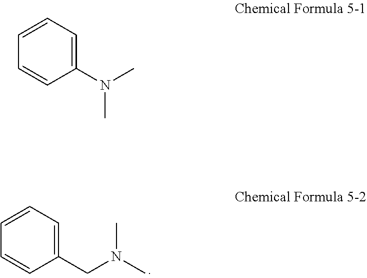

9. The resin composition according to claim 1, wherein an amount of the organic solvent is about 60 wt % to about 90 wt % relative to 100 wt % of a total weight of the resin composition, and the resin composition has a viscosity in a range from about 10 cP to about 30 cP.

10. The resin composition according to claim 9, wherein the organic solvent comprises one or more selected from among propylene glycol monomethyl ether (PGME) and propylene glycol methyl ether acetate (PGMEA).

11. A photosensitive resin composition, comprising:
solid content; and
an organic solvent,
wherein the solid content comprises: a resin material comprising a material comprising a hydroxyl group, an acrylate-based material, and a material comprising a polycyclic group; a photosensitizer comprising a photo active compound (PAC); a plasticizer; an initiator; and a surfactant.

12. The photosensitive resin composition according to claim 11,
wherein an amount of the material comprising the hydroxyl group is about 40 wt % to about 70 wt % relative to 100 wt % of a total weigh of the solid content,
wherein an amount of the acrylate-based material is about 1 wt % to about 20 wt % relative to 100 wt % of the total weight of the solid content,
wherein an amount of the material comprising the polycyclic group is about 1 wt % to about 20 wt % relative to 100 wt % of the total weight of the solid content.

13. The photosensitive resin composition according to claim 12,
wherein the material comprising the hydroxyl group comprises a material represented by Chemical Formula 6-1,
wherein the acrylate-based material comprises a material represented by Chemical Formula 6-2, and
wherein the material comprising the polycyclic group comprises a material represented by Chemical Formula 6-3:

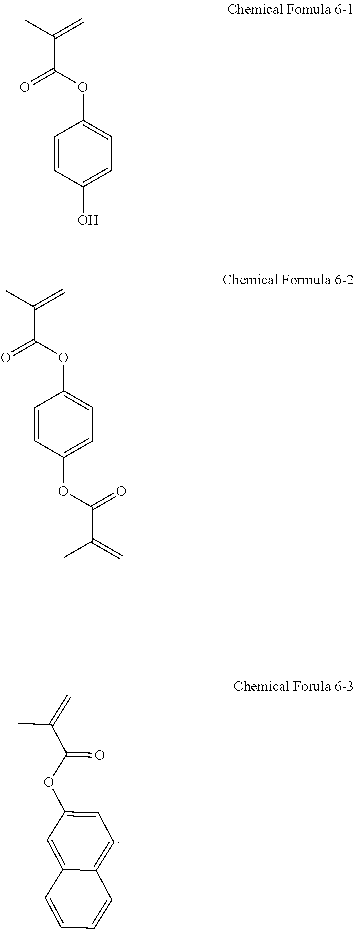

14. The photosensitive resin composition according to claim 11,
wherein an amount of the photosensitizer is about 0.2 wt % to about 20 wt % relative to 100 wt % of a total weight of the solid content,
wherein an amount of the plasticizer is about 0.1 wt % to about 10 wt % relative to 100 wt % of the total weight of the solid content, and
wherein an amount of the initiator is about 2 wt % to about 20 wt % relative to 100 wt % of the total weight of the solid content.

15. The photosensitive resin composition according to claim 14,
wherein the photosensitizer comprises one or more selected from among a material represented by Chemical Formula 7-1, a material represented by Chemical Formula 7-2, and a material represented by Chemical Formula 7-3,
wherein the plasticizer comprises a material represented by Chemical Formula 8, and
wherein the initiator comprises one or more selected from among a material represented by Chemical Formula 9-1, a material represented by Chemical Formula 9-2, a material represented by Chemical Formula 9-3, a material represented by Chemical Formula 9-4, a material represented by Chemical Formula 9-5, a material represented by Chemical Formula 9-6, and a material represented by Chemical Formula 9-7:

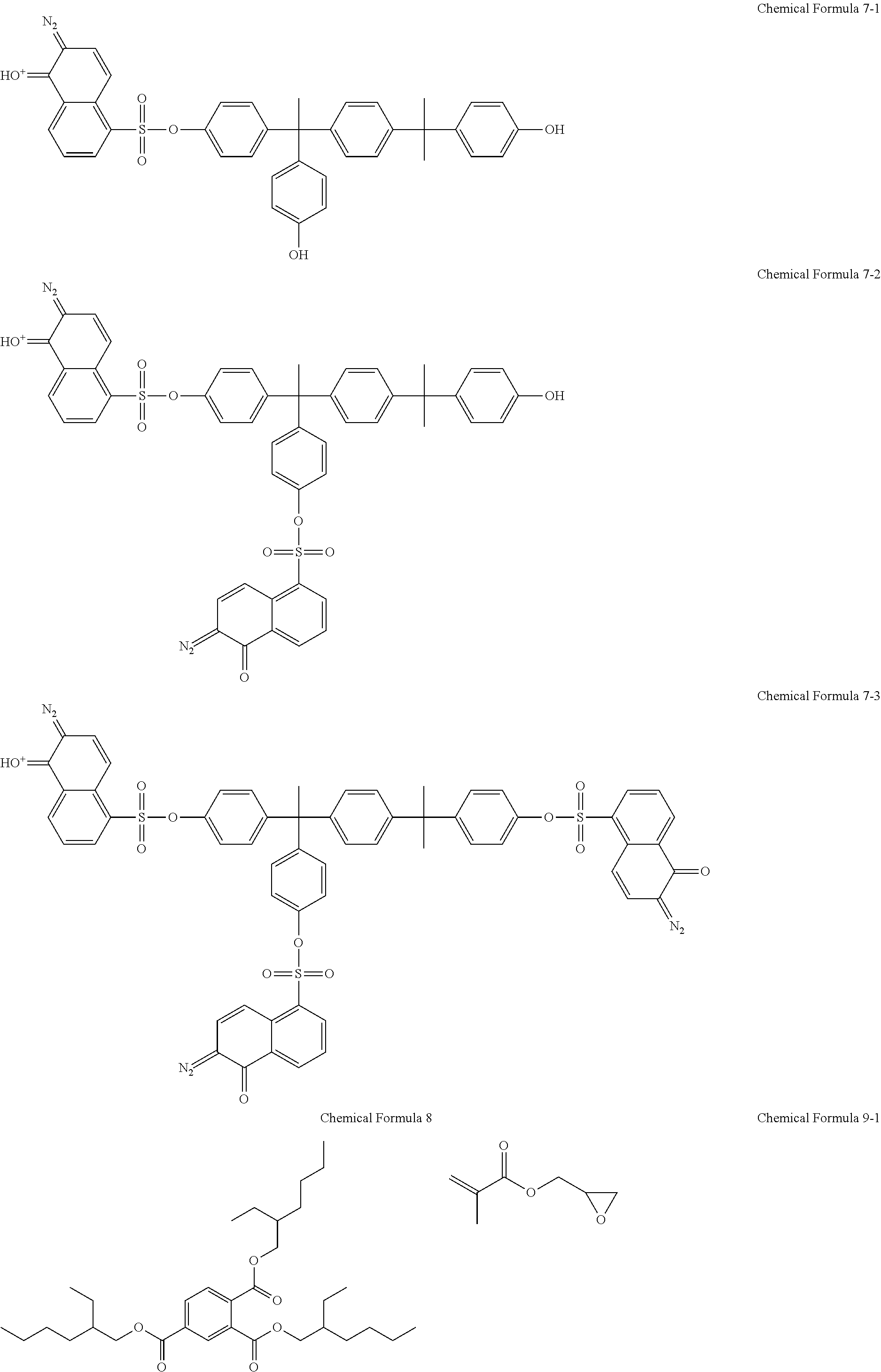

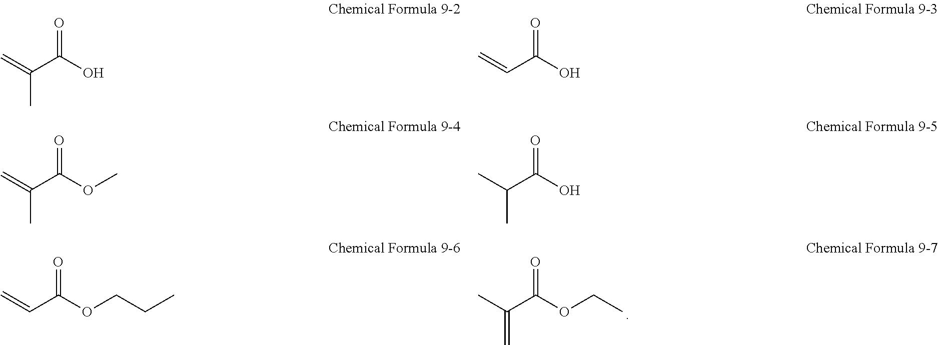

16. The photosensitive resin composition according to claim 11, wherein the surfactant comprises one or more selected from among a fluoro-based surfactant and a silicon-based surfactant.

17. The photosensitive resin composition according to claim 16, wherein an amount of the surfactant is about 0.05 wt % to about 3 wt % relative to 100 wt % of a total weight of the solid content.

18. The photosensitive resin composition according to claim 11, wherein the organic solvent comprises propylene glycol monomethyl ether (PGME).

19. The photosensitive resin composition according to claim 18, wherein an amount of the organic solvent is about 60 wt % to about 90 wt % relative to 100 wt % of a total weight of the photosensitive resin composition.

20. A method of fabricating a display device, the method comprising:
forming a display layer; and
forming a lens layer on the display layer,
wherein forming the lens layer comprises: forming a base lens layer comprising a resin composition; and patterning lenses by removing at least a portion of the base lens layer,
wherein the resin composition comprises: solid content; and an organic solvent,
wherein the solid content comprises: a resin material comprising a carbazole-based material and an acrylate-based material; a multifunctional cross-linker; an initiator comprising a thermal initiator and a photoinitiator; and a sensitizer.

21. The method according to claim 20, wherein forming the base lens layer comprises performing a process of curing the base lens layer.

22. The method according to claim 20,
wherein forming the lens layer further comprises: forming a base photosensitive resin composition layer on the base lens layer; and patterning an etching mask by removing at least a portion of the base photosensitive resin composition layer,
wherein the base photosensitive resin composition layer comprises: solid content; and an organic solvent, and
wherein the solid content in the base photosensitive resin composition layer comprises: a resin material comprising a material comprising a hydroxyl group, an acrylate-based material, and a material comprising a polycyclic group; a photosensitizer comprising a photo active compound (PAC); a plasticizer; an initiator; and a surfactant.

23. The method according to claim 22, wherein forming the lens layer further comprises forming an interlayer insulating layer on the base lens layer before forming the base photosensitive resin composition layer.

24. The method according to claim 20, wherein forming the lens layer comprises directly patterning the base lens layer without forming a layer based on a photosensitive material on the base lens layer.

25. A display device manufactured by the method according to claim 20,
wherein the display layer comprises a silicon substrate, a light emitting element on the silicon substrate, and a color filter on the light emitting element, and
wherein the lens layer is on the color filter.

26. The display device according to claim 25, wherein the lens layer has a thickness in a range from about 2.7 μm to about 3.3 μm.

27. An electronic device, comprising:
a processor configured to provide input image data;
a display device manufactured by the method according to claim 20, and configured to display an image based on the input image data, the display device including sub-pixel areas; and
a power supply configured to supply power to the display device.
